(19) United States
(12) Patent Application Publication
(10) Pub. No.: US 2026/0136629 A1
(43) Pub. Date: May 14, 2026

(54) SEMICONDUCTOR STRUCTURE WITH BACKSIDE VIA AND METHOD FOR FORMING SAME

(71) Applicant: Taiwan Semiconductor Manufacturing Company, Ltd., Hsin-Chu (TW)

(72) Inventors: Yu-Chun Lin, Hsinchu (TW); Po-Yu Huang, Hsinchu (TW); Chen-Ming Lee, Taoyuan County (TW); I-Wen Wu, Hsinchu City (TW); Mei-Yun Wang, Hsinchu (TW)

(21) Appl. No.: 19/086,605

(22) Filed: Mar. 21, 2025

Related U.S. Application Data
(60) Provisional application No. 63/719,403, filed on Nov. 12, 2024.

(51) Int. Cl. H10D 64/23; H10D 30/00; H10D 30/01; H10D 62/10

(52) U.S. Cl. CPC H10D 64/256; H10D 30/0198; H10D 30/501; H10D 64/258; H10D 62/116

(57) ABSTRACT

A method of the present disclosure includes forming a stack on a substrate, patterning the stack and the substrate to form first and second active regions, forming an isolation structure between the first and second active regions, depositing an isolation structure protecting layer on the isolation structure, forming a dummy gate stack across the first and second active regions, recessing the first and second active regions to form first and second trenches, forming first and second source/drain features in the first and second trenches, removing the dummy gate stack to form a gate trench, depositing a gate structure in the gate trench and interfacing the isolation structure protecting layer, thinning the substrate and the isolation structure, forming a backside opening exposing a bottom surface of the first source/drain feature, and forming a backside via in the backside opening and in electrical coupling with the first source/drain feature.

### PRIORITY DATA

This application claims priority to U.S. Provisional Patent Application No. 63/719,403, filed on Nov. 12, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Conventionally, ICs are built in a stacked-up fashion, having transistors at the lowest level and interconnect (vias and wires) on top of the transistors to provide connectivity to the transistors. Power rails (such as metal lines for voltage sources and ground planes) are also above the transistors and may be part of the interconnect. As the integrated circuits continue to scale down, so do the power rails, which may lead to increased voltage drop across the power rails and increased power consumption of the integrated circuits. Besides power rails, signal lines may also suffer from such scaling down, such as the ever-reduced signal line pitches that may lead to increased parasitic capacitance and reduced circuit speed. Therefore, although existing approaches in semiconductor fabrication have been generally adequate for their intended purposes, they have not been entirely satisfactory in all respects. One area of interest is how to form vias on the backside of an IC, with a reduced height for resistance reduction.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2 illustrates a perspective view of a work-in-progress (WIP) structure, according to one or more aspects of the present disclosure.

FIGS. 3-43 illustrate fragmentary top and cross-sectional views of the WIP structure during a fabrication process according to the method of FIG. 1, according to one or more aspects of the present disclosure.

FIGS. 44-46 illustrate fragmentary cross-sectional views of an alternative embodiment of the WIP structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art.

This application generally relates to semiconductor structures and fabrication processes, and more particularly to integrate circuit (IC) chips having transistors with backside interconnect structure that includes backside metal lines and backside vias.

An object of the present disclosure is to provide an interconnect structure (e.g., power rails and/or signal lines) on the backside of a semiconductor device containing transistors, in addition to an interconnect structure (including power rails and signal lines) on the frontside of the semiconductor device. In particular, this disclosure addresses the formation of vias on the backside of a semiconductor device with reduced height to achieve resistance reduction. The interconnect structure and vias formed on the backside are also referred to as the backside interconnect structure and backside vias, respectively, in contrast to the frontside interconnect structure and frontside vias formed on the frontside. The backside vias connect the backside power rails and/or signal lines to source/drain features formed on the frontside. Since via resistance generally correlates with its height, reducing the via height effectively decreases via resistance and consequently the overall resistance in electrical routing. For backside vias, the minimum height is often constrained by the thickness of the isolation structure (e.g., a shallow trench isolation (STI) structure) deposited between active regions, on which bottom surfaces of metal gate structures lands. This isolation structure often has to be sufficiently thick to prevent metal gate structures from being exposed during the backside thinning process. However, a thicker isolation structure requires longer backside vias, which have to travel through the thickness of the isolation structure to connect the backside metal lines to the source/drain features.

The present disclosure provides a method for forming backside vias with reduced height. In some embodiments, after an isolation structure is formed between active regions, an isolation structure protecting layer is deposited on the frontside of the isolation structure. Subsequently, metal gate structures are formed on the isolation structure protecting layer, rather than directly on the isolation structure. This approach allows the minimum thickness of the isolation structure to be reduced, as the isolation structure no longer undergoes etching loss during the frontside manufacturing steps. The isolation structure protecting layer also serves as a thinning stop layer, preventing metal gate structures from being exposed during the backside thinning process. With the inclusion of the isolation structure protecting layer, the isolation structure can be substantially removed during the backside process, significantly reducing the backside via height and the associated resistance.

The details of the structure and fabrication methods of the present disclosure are described below in conjunction with the accompanied drawings, which illustrate a process of making multi-gate transistors, particularly gate-all-around (GAA) transistors, according to some embodiments. A GAA transistor refers to a transistor having vertically-stacked horizontally-oriented channel members, such as in the form of nanowires and/or nanosheets. GAA transistors are promising candidates to take CMOS to the next stage of the roadmap due to their better gate control ability, lower leakage current, and fully field effect transistor (FET) layout compatibility. For the purposes of simplicity, the present disclosure uses GAA transistors as an example. Those of ordinary skill in the art should appreciate that they may readily use the present disclosure as a basis for designing or modifying other processes and structures (such as FinFET transistors) for carrying out the same purposes and/or achieving the same advantages of the embodiments introduced herein.

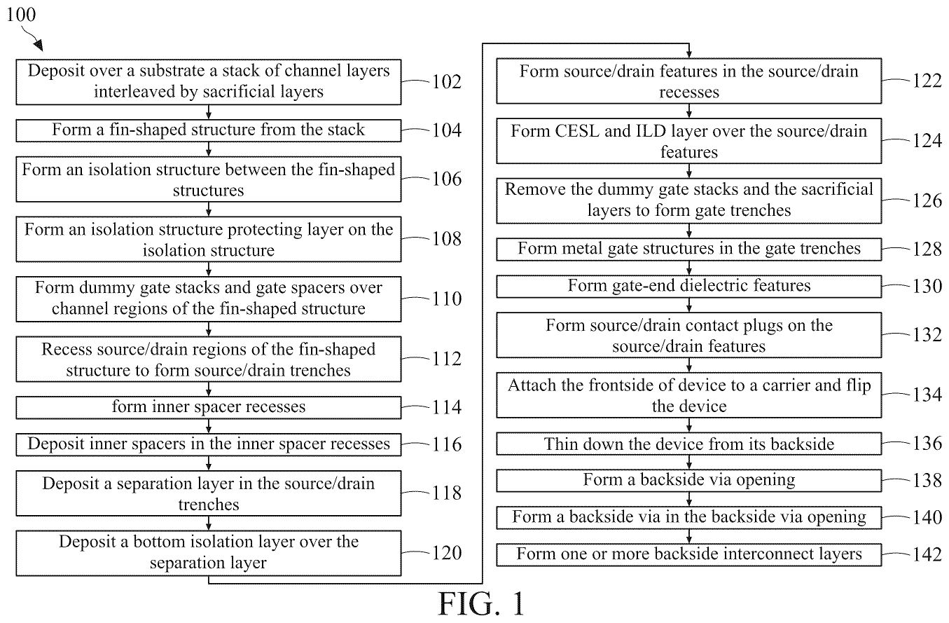

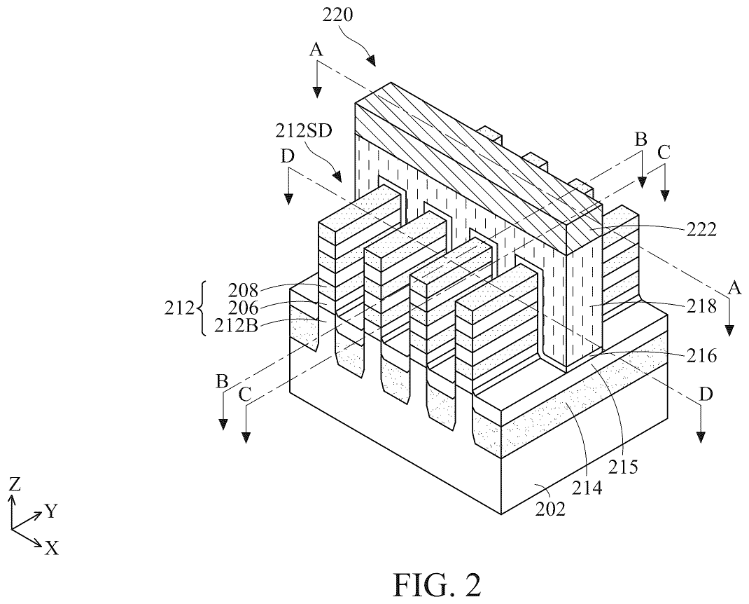

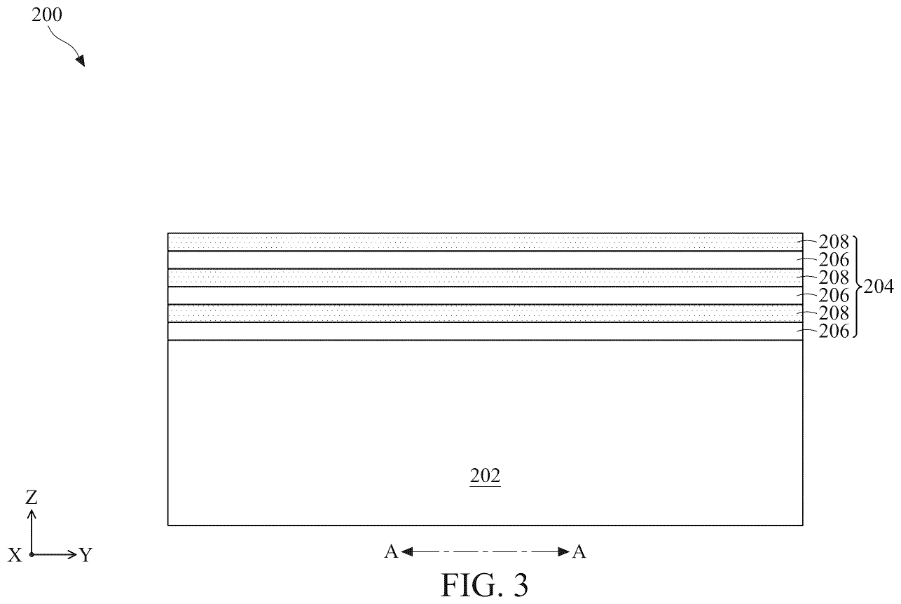

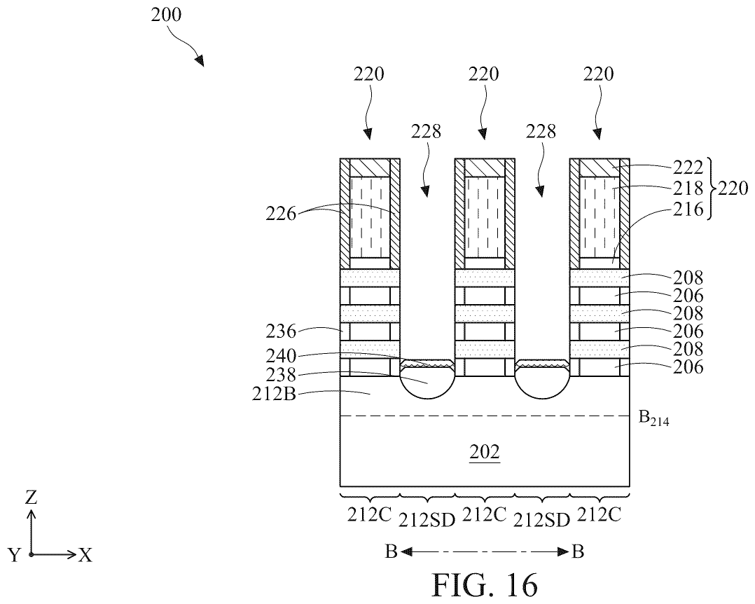

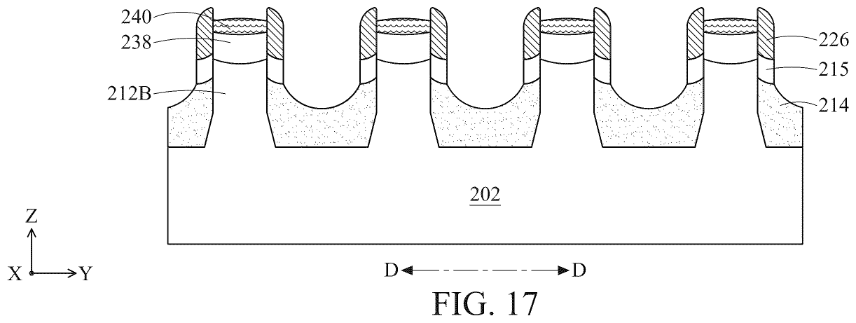

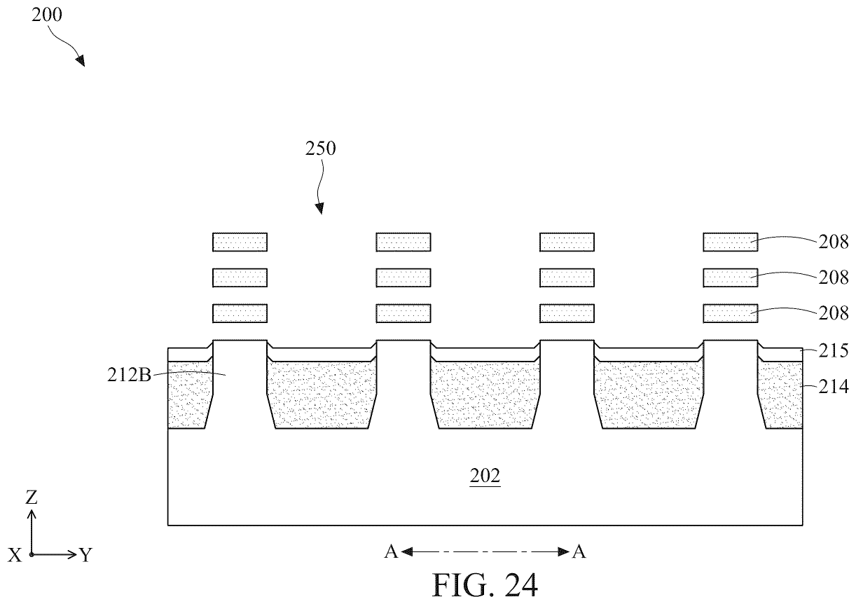

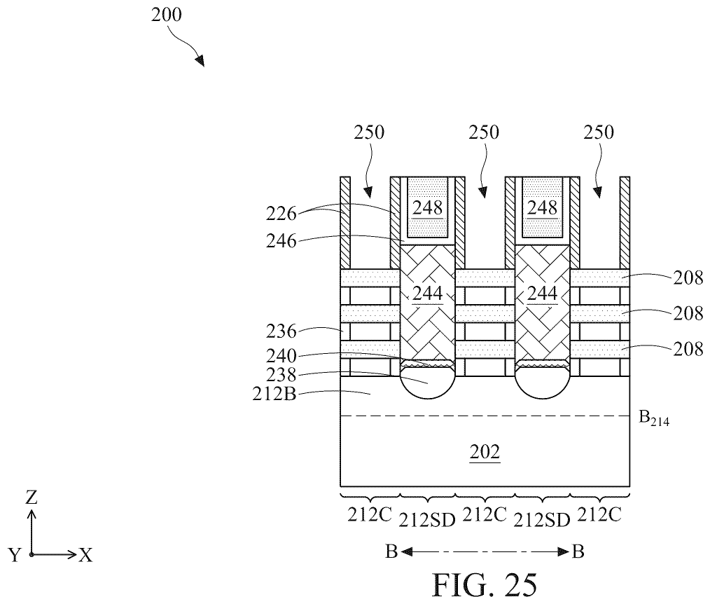

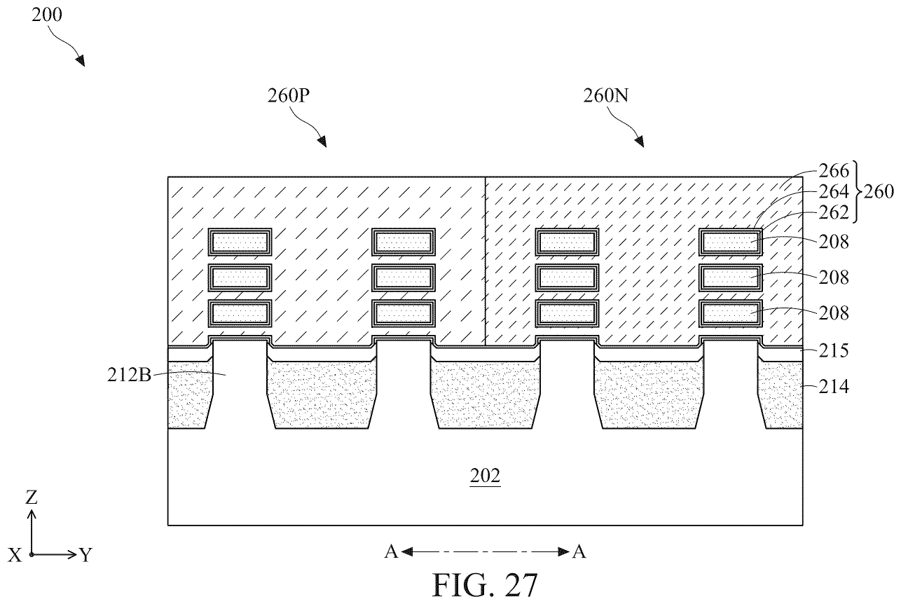

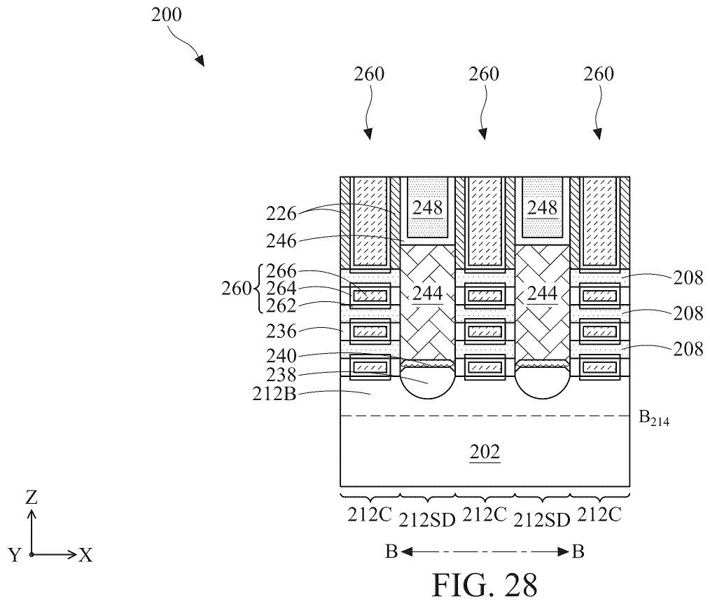

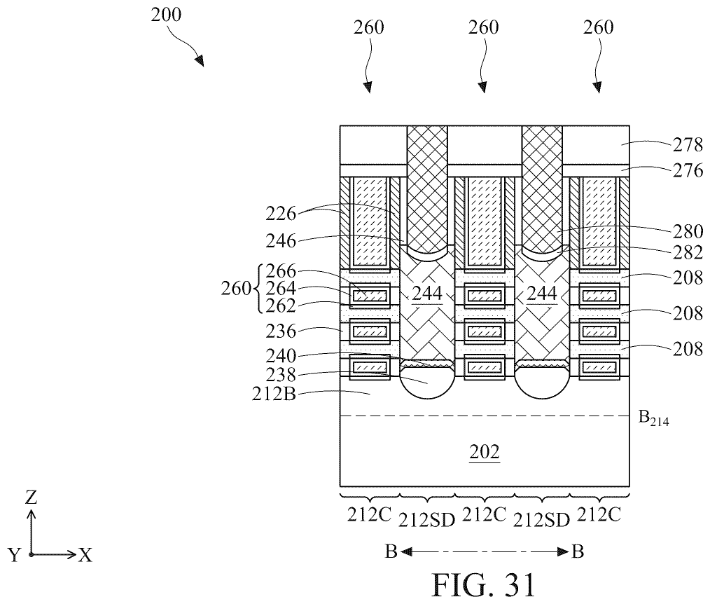

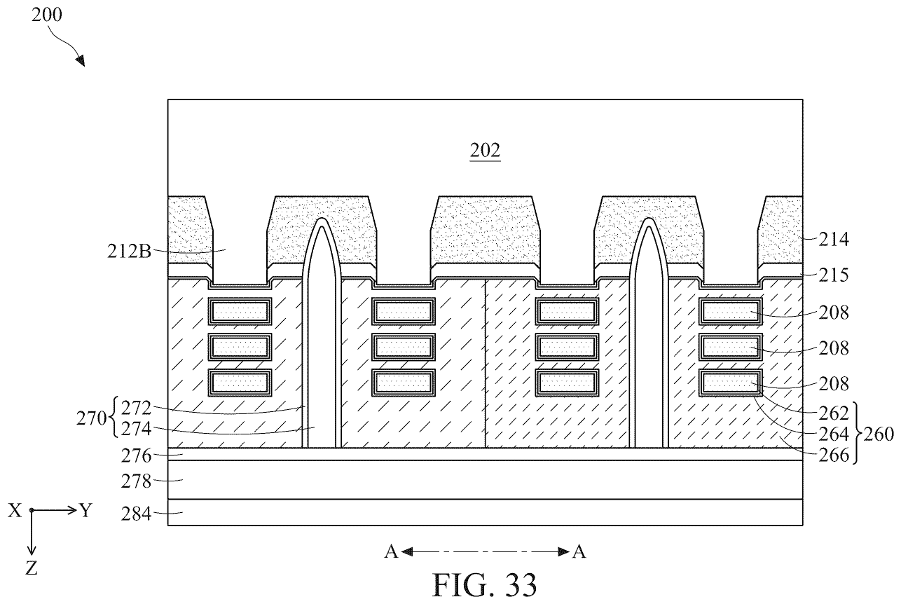

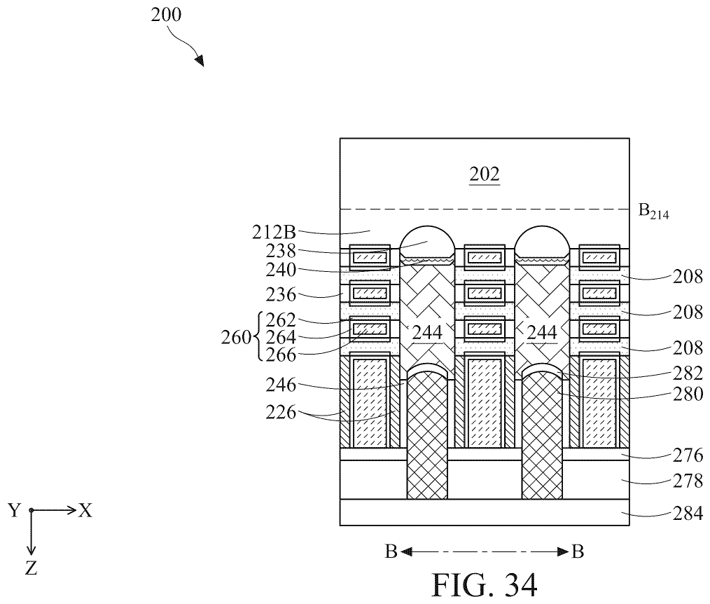

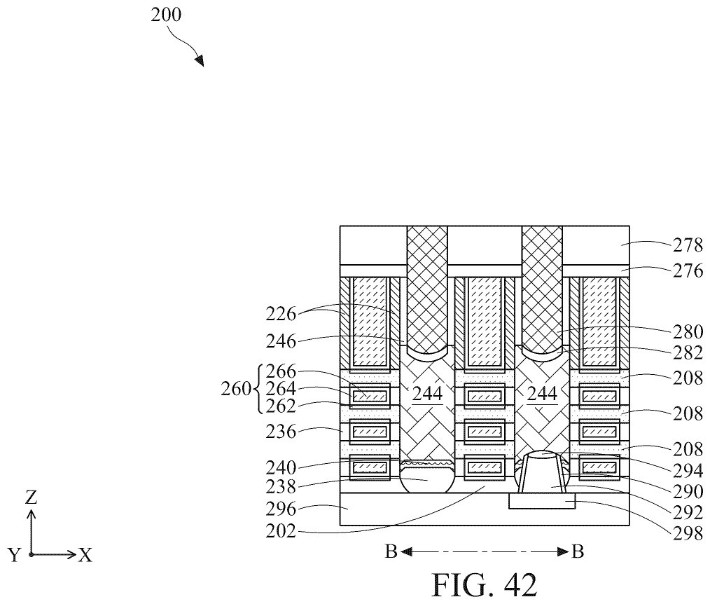

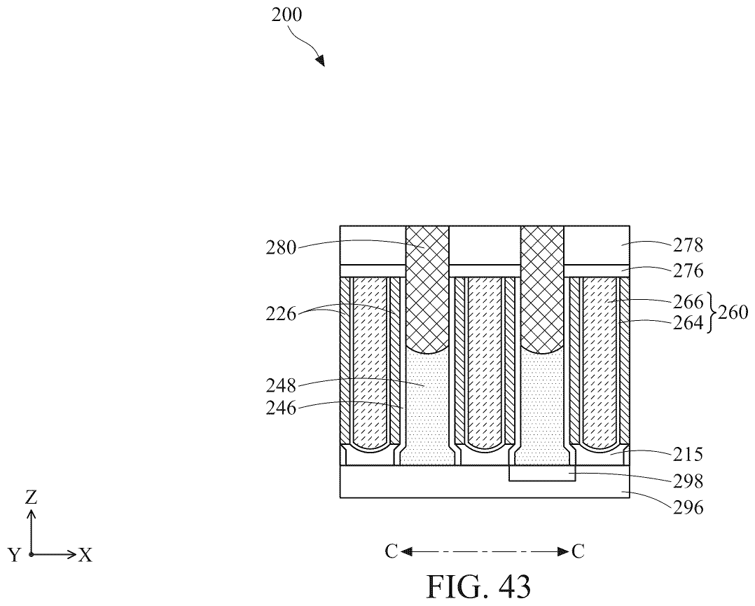

FIG. 1 shows a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-46. FIG. 2 is a perspective view of a WIP structure 200, and FIGS. 3-46 are fragmentary cross-sectional views (e.g., a cut along A-A, B-B, C-C, or D-D line as illustrated in FIG. 2) of the WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-46 are perpendicular to one another. Throughout the present disclosure, unless expressly described otherwise, like reference numerals denote like features or steps.

FIG. 2 illustrates an example of the semiconductor device 200 in a perspective view, in accordance with some embodiments. The semiconductor device 200 as illustrated in FIG. 1 is at a stage of fabrication during which dummy gate stacks 220 are disposed across the fin-shaped structures 212. Each of the dummy gate stacks 220 includes a dummy dielectric layer 216, a dummy electrode layer 218, and a gate-top hard mask layer 222. The fin-shaped structures 212 protrude from a substrate 202. Each of the fin-shaped structures 212 include a fin-shaped base 212B, and an epitaxial stack of channel layers 208 and sacrificial layers 206 interleaved in a vertical direction. The channel layers 208 in the form of nanostructures (e.g., nanosheets or nanowires) are interleaved with the sacrificial layers 206. Source/drain regions 212SD are defined on opposing sides of the dummy gate stacks 220. An isolation structure 214 and an isolation structure protecting layer 215 atop are formed on opposing sides of the fin-shaped structures 212.

FIG. 2 further illustrates reference cross-sections that are used in later figures. Cross-section A-A is along a longitudinal axis of the dummy gate stacks 220 and in a direction, for example, perpendicular to the direction of current flow between the source/drain regions 212SD of the respective GAA transistors of the semiconductor device 200. Cross-section B-B is perpendicular to cross-section A-A and is along a longitudinal axis of the fin-shaped structure 212 and in a direction of, for example, a current flow between the source/drain regions 212SD of the respective GAA transistors of the semiconductor device 200. Cross-section C-C is parallel to cross-section B-B and between two neighboring fin-shaped structures 212. Cross-section D-D is parallel to cross-section A-A and extends through source/drain regions 212SD of the semiconductor device 200. Subsequent figures each refer to these reference cross-sections for clarity.

Referring to FIGS. 1 and 3, method 100 includes a block 102 where a stack 204 of alternating semiconductor layers is formed over the semiconductor device 200. As shown in FIG. 3, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 atop the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor compositions are different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

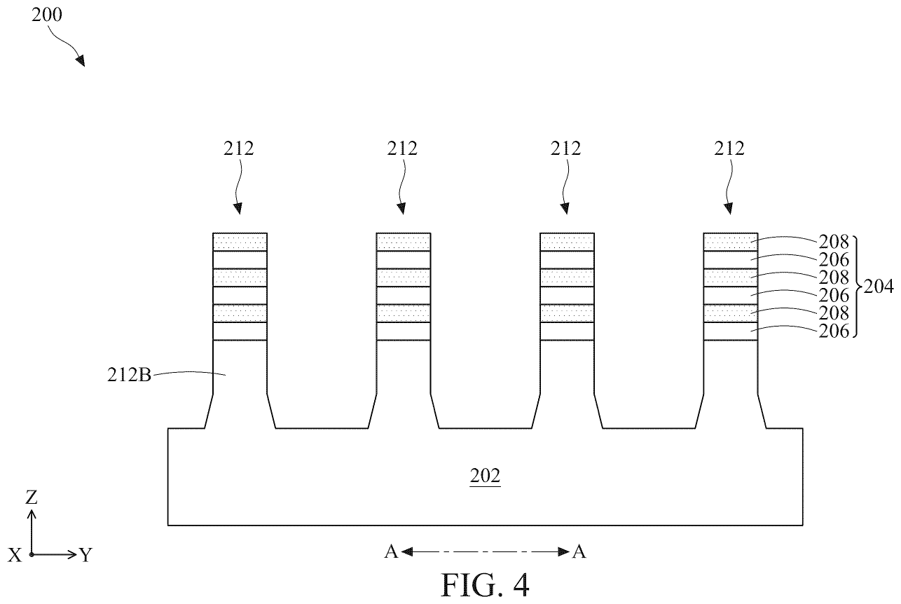

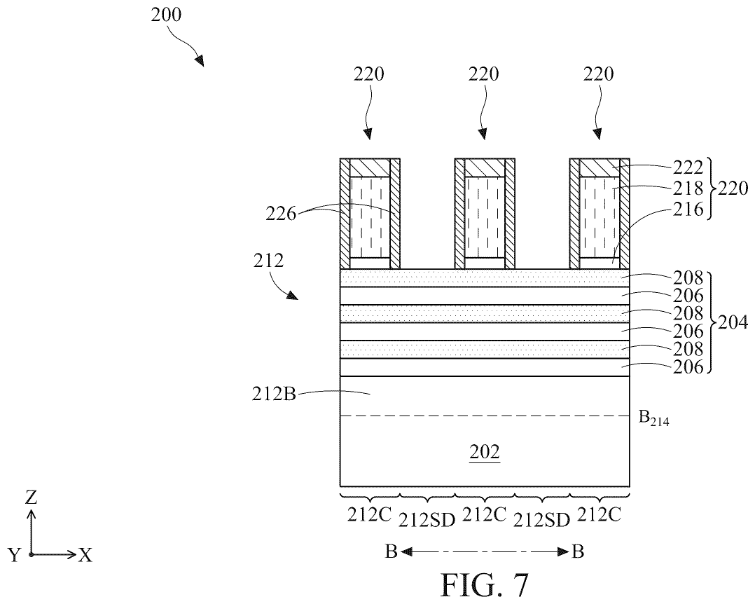

Referring to FIGS. 1 and 4, method 100 includes a block 104 where fin-shaped structures 212 are formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structures 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 4, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 extends vertically along the Z direction and lengthwise along the Y direction. The fin-shaped structure 212 provides an active region (also referred to as active region 212) for the subsequently-formed transistors, which includes channel regions (denoted as 212C, as shown in FIG. 7) and source/drain regions (denoted as 212SD, as shown in FIG. 7). As shown in FIG. 4, the fin-shaped structure 212 includes a fin-shaped base 212B patterned from the substrate 202 and the patterned stack 204 disposed directly over the fin-shaped base 212B. In the illustrated embodiment as shown in FIG. 4, the patterned stack 204 and the top portion of the fin-shaped base 212B have substantially straight sidewalls; while the bottom portion of the fin-shaped base 212B has tapering sidewalls due to loading effect during the patterning process.

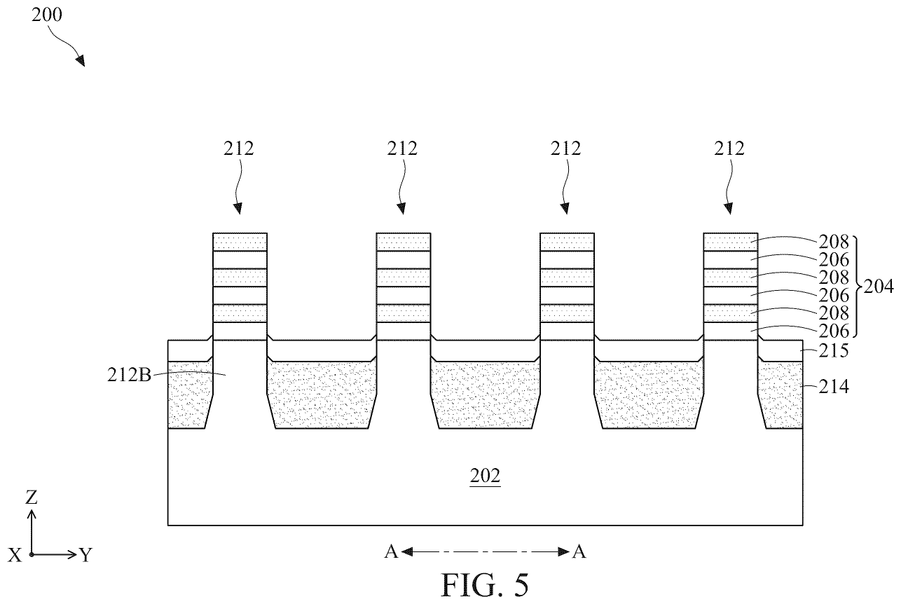

Referring to FIGS. 1 and 5, method 100 includes a block 106 where an isolation structure 214 (or referred to as isolation feature 214) is formed around the fin-shaped base 212B of the fin-shaped structures 212. In some embodiments represented in FIG. 5, the isolation structure 214 is disposed on sidewalls of the fin-shaped base 212B. In some embodiments, the isolation structure 214 may be formed in the trenches to isolate adjacent active regions residing in the fin-shaped structures 212. In some embodiments, the isolation structure 214 is a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation structure 214 shown in FIG. 5. In the illustrated embodiment, the top surface of the isolation structure 214 has a dishing profile due to loading effect during etching process. The fin-shaped structures 212 rise above the isolation structure 214 after the recessing, while the fin-shaped base 212B is at least partially embedded or buried in the isolation structure 214. In the illustrated embodiment, the edge of the dishing profile of the isolation structure 214 intersects sidewalls of the top portion of the fin-shape base 212B. Alternatively, the edge of the dishing profile of the isolation structure 214 may intersect sidewalls of the bottommost sacrificial layer 206, such that the fin-shaped base 212B is fully embedded or buried in the isolation structure 214.

Still referring to FIGS. 1 and 5, method 100 includes a block 108 where an isolation structure protecting layer 215 is formed over the isolation structure 214 and around a top portion of the fin-shaped base 212B. A composition of the isolation structure protecting layer 215 is different from a composition of the isolation structure 214. In some embodiments, the isolation structure 214 includes silicon oxide (SiOx, e.g., SiO₂), and the isolation structure protecting layer 215 includes silicon nitride (SiₓN_{y}, e.g., Si₃N₄), silicon carbonitride (SiCN), or silicon oxynitride (SiON). By way of example, in some embodiments, a nitride-containing material is first deposited over the isolation structure 214, filling the trenches with nitride. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the isolation structure protecting layer 215. In the illustrated embodiment, the top surface of the isolation structure protecting layer 215 has a dishing profile due to loading effect during etching process. The fin-shaped structures 212 rise above the isolation structure protecting layer 215 after the recessing. In the illustrated embodiment, the edge of the dishing profile of the isolation structure protecting layer 215 intersects sidewalls of the bottommost sacrificial layer 206. The middle point of the dishing profile (e.g., the lowest point of the top surface) of the isolation structure protecting layer 215 may be above or alternatively below the bottom surface of the bottommost sacrificial layer 206. The fin-shaped base 212B is embedded or buried in the combination of the isolation structure 214 and the isolation structure protecting layer 215. A thickness of the isolation structure protecting layer 215 may range from about 10 nm to about 50 nm. This range is not arbitrary or trivial. If the thickness is less than about 10 nm, the isolation structure protecting layer 215 may itself be etched through due to limited etching contrast in subsequent etching processes and compromise the protection function to the isolation structure 214. If the thickness is larger than about 50 nm, the bottommost sacrificial layer 206 may be buried thereunder and hard to be removed in subsequent replacement gate process.

Referring to FIGS. 1 and 6-7, method 100 includes a block 110 where dummy gate stacks 220 and gate spacers 226 are formed over channel regions 212C of the fin-shaped structure 212. The dummy gate stacks 220 serve as a placeholder to undergo various processes and are to be removed and replaced by functional gate structures. Other processes and configuration are possible. As shown in FIG. 7, the dummy gate stacks 220 and gate spacers 226 are formed over the fin-shaped structure 212, and the fin-shaped structure 212 may be divided into channel regions 212C underlying the dummy gate stacks 220 and the gate spacers 226 and source/drain regions 212SD that do not underlie the dummy gate stacks 220 and the gate spacers 226. The channel regions 212C are adjacent to the source/drain regions 212SD. As shown in FIG. 7, the channel region 212C is disposed between two source/drain regions 212SD along the X direction. As used herein, a source/drain region, or “S/D region,” may refer to a region that provides a source and/or drain for one or multiple devices. It may also refer to a source or a drain of one or multiple devices. Also, in FIG. 7 (as well as in following figures showing the cross-sectional view in the X-Z plane), a horizontal dotted line B₂₁₄ marks the position of the bottom surface of the isolation structure 214.

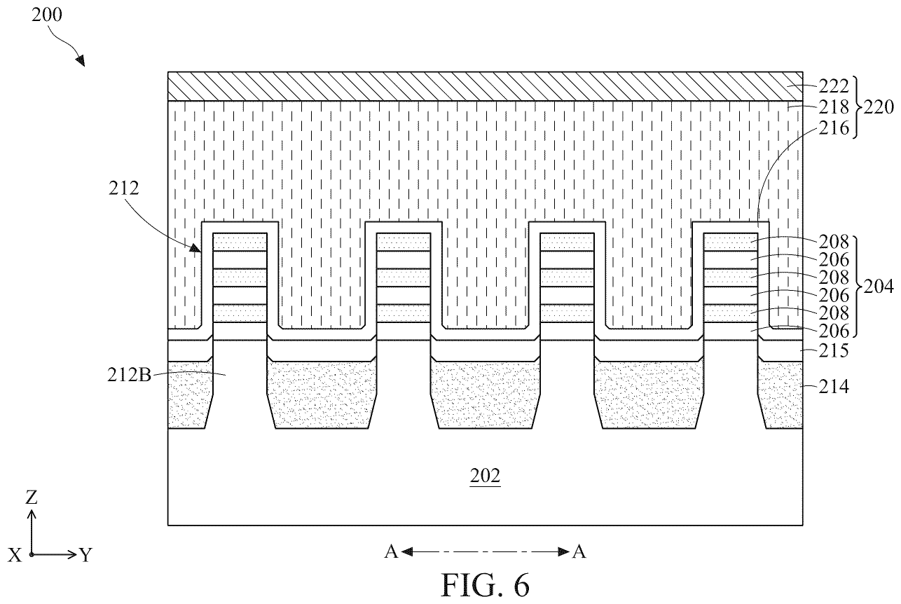

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the semiconductor device 200. The dummy dielectric layer 216 may be conformally deposited on the fin-shaped structure 212 using a chemical vapor deposition (CVD) process, an atomic layer deposition (ALD) process, an oxygen plasma oxidation process, or other suitable processes. The term “conformally” may be used herein for ease of description of a layer having substantially uniform thickness over various regions. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stacks 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 is a bi-layer structure, which may include a silicon oxide layer and a silicon nitride layer over the silicon oxide layer.

The formation of the gate spacers 226 may include deposition of a gate spacer layer and etching back the gate spacer layer. In some embodiments, the gate spacer layer is deposited conformally over the semiconductor device 200, including over top surfaces and sidewalls of the dummy gate stacks 220. The gate spacer layer may be a single layer or a multi-layer. The at least one layer in the gate spacer layer may include silicon carbonitride, silicon oxycarbide, silicon oxycarbonitride, or silicon nitride. The gate spacer layer may be deposited over the dummy gate stack 220 using processes such as, a CVD process, a subatmospheric CVD (SACVD) process, an ALD process, or other suitable process. Subsequently, an anisotropic etching process may be implemented to remove horizontal portions of the gate spacer layer from top-facing surfaces of the semiconductor device 200, including from top-surfaces of the dummy gate stacks 220. The remaining vertical portions of the gate spacer layer covers sidewalls of the dummy gate stacks 220 as the gate spacers 226.

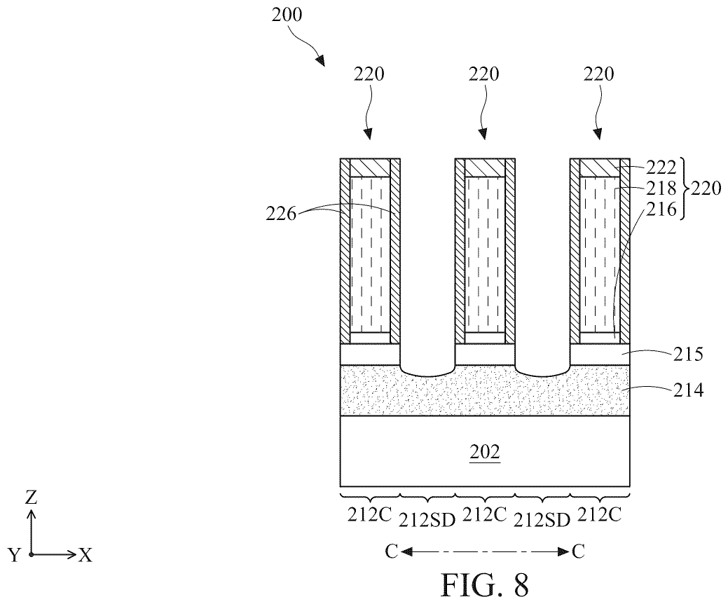

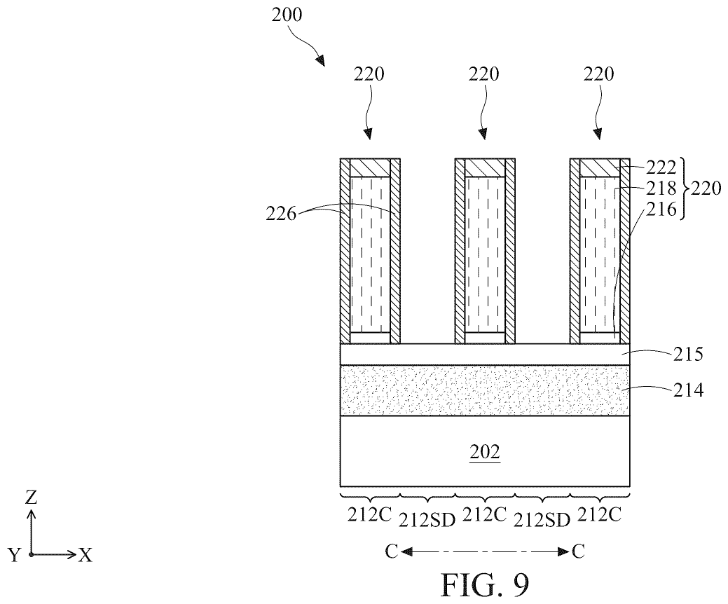

FIGS. 8 and 9 illustrate two alternative embodiments of the semiconductor device 200 along the cross-section C-C at the conclusion of operations at the block 110. Common in both FIGS. 8 and 9, between adjacent fin-shaped structures 212, the bottom surfaces of the dummy gate stacks 220 and the gate spacers 226 land directly on the top surface of the isolation structure protecting layer 215. In the illustrated embodiment as shown in FIG. 8, the anisotropic etching process in removing horizontal portions of the gate spacer layer also etches through the isolation structure protecting layer 215 between opposing gate spacers 226, and consequently the top portion of the isolation structure 214 after being exposed may also suffer some etch loss due to limited etching contrast. In the illustrated embodiment as shown in FIG. 9, the isolation structure protecting layer 215 remains substantially intact after the anisotropic etching process in removing horizontal portions of the gate spacer layer. An additional etching process other than the anisotropic etching process in removing horizontal portions of the gate spacer layer may be optionally performed to open the isolation structure protecting layer 215 between opposing gate spacers 226, which leads to the resultant structure as shown in FIG. 8. Alternatively, the source/drain recessing process as discussed below may etch through the isolation structure protecting layer 215 between opposing gate spacers 226.

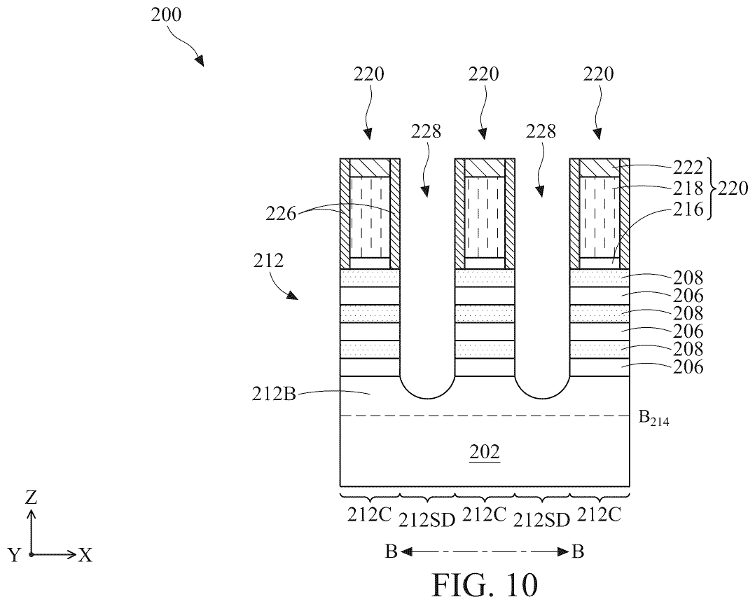

Referring to FIGS. 1 and 10-12, method 100 includes a block 112 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202 (i.e., the fin-shaped base 212B is partially recessed). An example dry etching process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 10, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

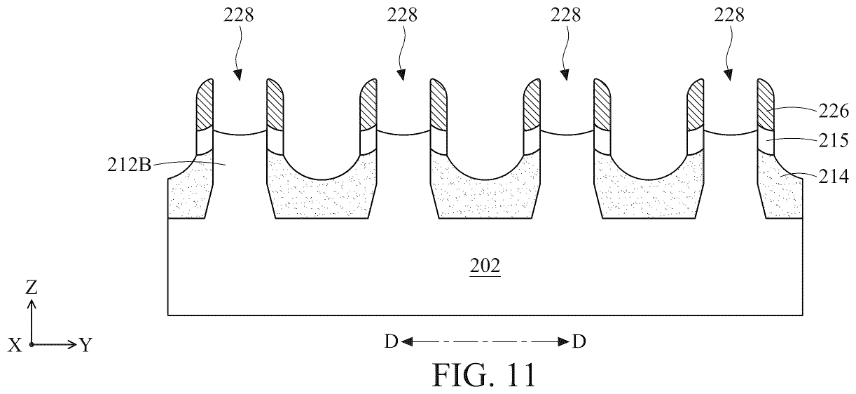

As illustrated in FIG. 11, over the source/drain regions 212SD, the majority of the fin-shaped structure 212 is etched away and a top surface of the fin-shaped base 212B is exposed in the source/drain region 212SD. Further, the recessed top surface of the fin-shaped base 212B may be lower than the bottom surface of the isolation structure protecting layer 215. Because the gate spacers 226 are etched at a slower rate than the fin-shaped structure 212, the gate spacers 226 in the source/drain region 212SD rise above the top surface of the fin-shaped base 212B. The remaining gate spacers 226 in the source/drain region 212SD are also referred to as fin spacers. The fin spacers protect portions of the isolation structure protecting layer 215 directly underneath from being removed during the recessing of the source/drain regions 212SD. If the isolation structure protecting layer 215 has not been opened in previous operations (as shown in FIG. 9), it is opened during the recessing of the source/drain regions 212SD.

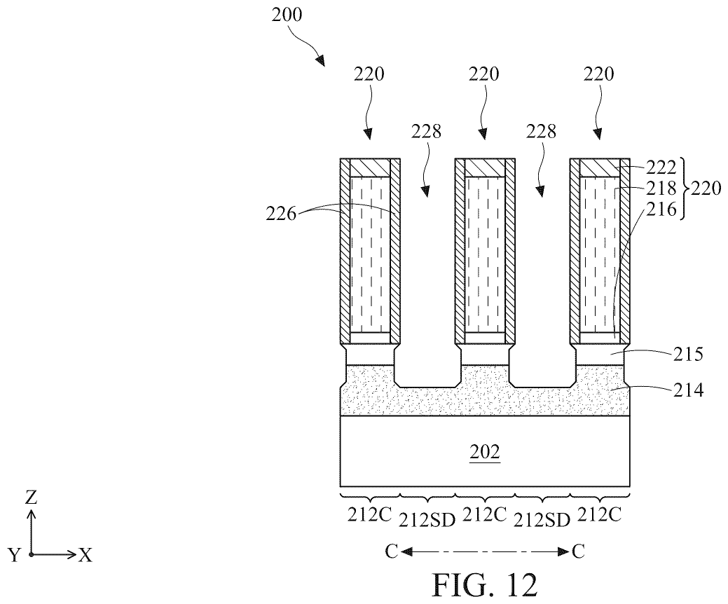

As illustrated in FIG. 12, the etching process performed during the recessing of the source/drain regions 212SD etches into the exposed portion of the isolation structure 214. This process further expands the cavity (i.e., the bottom portion of trench 228) beneath the isolation structure protection layer 215, resulting in a cavity width that exceeds the lateral spacing between the opposing gate spacers 226. In other words, a portion of the cavity may extend directly beneath the gate spacers 226. Additionally, the bottom portion of the isolation structure protection layer 215 may be laterally etched, causing the divided segments of the isolation structure protection layer 215 to take on an inverted trapezoidal appearance.

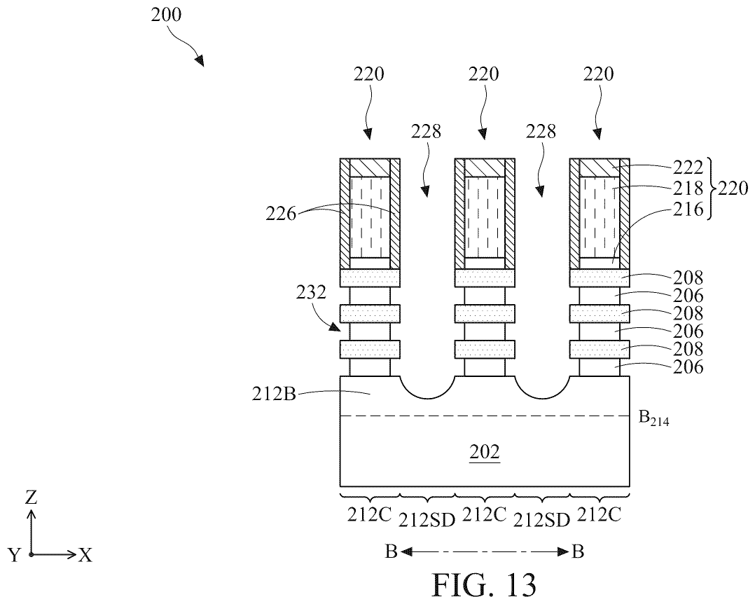

Referring to FIGS. 1 and 13, method 100 includes a block 114 where inner spacer recesses 232 are formed. The sacrificial layers 206 are selectively and partially recessed to form inner spacer recesses 232. The inner spacer recesses 232 may have a rectangular profile as illustrated. Alternatively, the inner spacer recesses 232 may have a concave profile bending away from the source/drain trenches 228. In an embodiment, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof.

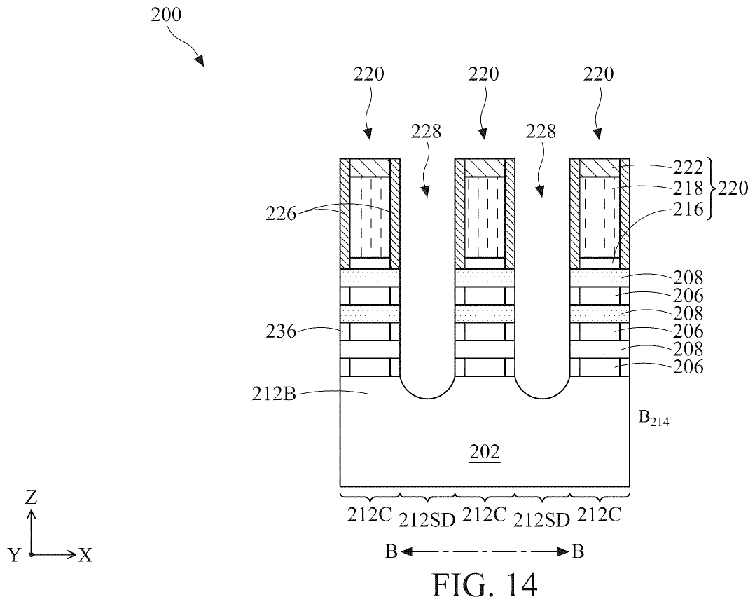

Referring to FIGS. 1 and 14, method 100 includes a block 116 where inner spacers 236 are formed in the inner spacer recesses 232. The formation of the inner spacers 236 may include the deposition of an inner spacer layer over exposed surfaces of the source/drain trenches 228, including filling the inner spacer recesses 232. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. Subsequently, the inner spacer layer is etched back to form inner spacers 236 in the inner spacer recesses 232. In some embodiments, the etching back of the inner spacer layer may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 236 substantially remain under the gate spacers 226 without extending to a position directly under the dummy gate stack 220. Alternatively, the inner spacers 236 may laterally extend to a position directly under the dummy gate stack 220.

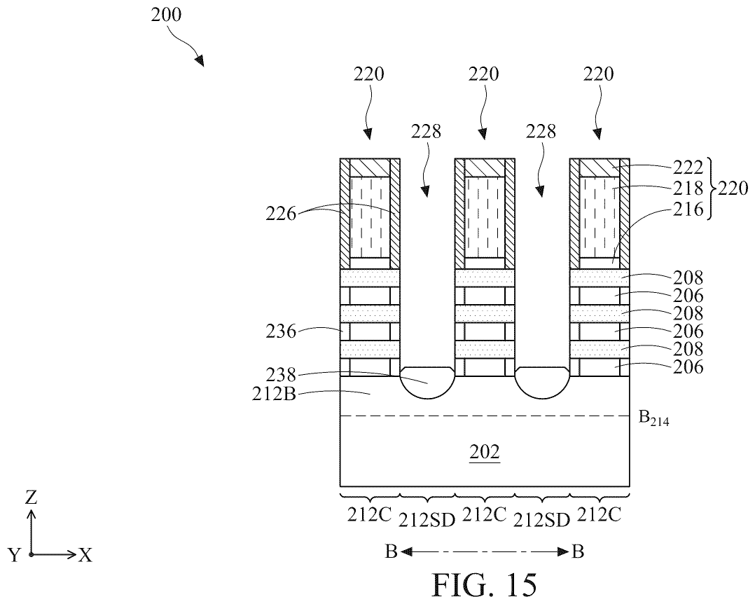

Referring to FIGS. 1 and 15, method 100 includes a block 118 where a separation layer (or separating layer) 238 is deposited in the bottom of the source/drain trenches 228. In some embodiments, the separation layer 238 is a buffer epitaxial layer epitaxially grown from the top surface of the fin-shaped base 212B. By way of example, epitaxial growth of the buffer epitaxial layer 238 may be performed by VPE, ultra-high vacuum CVD (UHV-CVD), MBE, and/or other suitable epitaxial grow processes. In some embodiments, the buffer epitaxial layer 238 includes the same material as the substrate 202, such as silicon. In some alternative embodiments, the buffer epitaxial layer 238 includes a different semiconductor material other than silicon, such as SiGe, SiSn, or other suitable semiconductor material. In some embodiments, the buffer epitaxial layer 238 is dopant-free, where for example, no intentional doping is performed during the epitaxial growth process. As a comparison, in one instance, the substrate 202 is lightly doped and has a higher doping concentration than the buffer epitaxial layer 238. The separation layer 238 provides a high resistance path from the S/D regions to the semiconductor substrate, such that the leakage current in the semiconductor substrate is suppressed. Notably, the formation of the separation layer 238, including manufacturing steps at block 118, may be optional. That is, the formation of the separation layer 238 may be omitted, and the separation layer 238 may not exist in the final structure, in some embodiments.

Referring to FIGS. 1 and 16-17, method 100 includes a block 120 where a bottom isolation layer 240 is formed over the separation layer 238 (or on the substrate 202 if the formation of the separation layer 238 is omitted). Because the bottom isolation layer 240 may interface source/drain features and oxygen content may oxidize source/drain features, the bottom isolation layer 240 may be formed of an oxygen-free dielectric material, such as a nitride. In an example process, a chlorine-containing silicon nitride layer is deposited over the source/drain trenches 228, including over a top surface of the buffer epitaxial layer 238. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etching process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etching process etches the chlorine-containing silicon nitride along sidewalls faster than it does relatively chlorine-free silicon nitride layer at the bottom of the source/drain trenches 228, the bottom isolation layer 240 may be formed over the buffer epitaxial layer 238. Notably, the formation of the bottom isolation layer 240, including manufacturing steps at block 120, may be optional. That is, the formation of the bottom isolation layer 240 may be omitted, and the bottom isolation layer 240 may not exist in the final structure, in some embodiments.

Referring to FIGS. 1 and 18-19, method 100 includes a block 122 where source/drain features 244 are epitaxially grown from the exposed semiconductor surfaces in the source/drain trenches 228, including from the sidewalls of the channel layers 208. While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, a sulfuric peroxide mixture, and/or hydrofluoric acid for oxide removal. The dry clean process may include helium (He) and hydrogen (H₂) treatment.

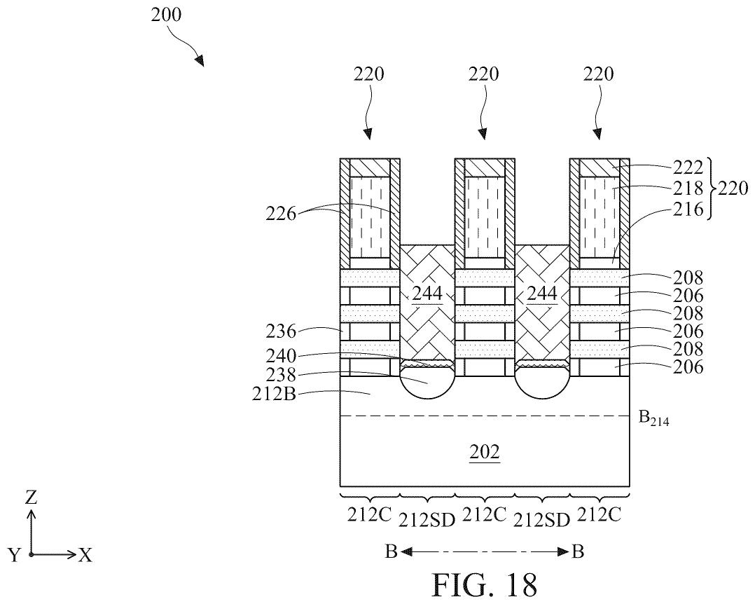

Reference is made to FIG. 18. The source/drain feature 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a lightly doped epitaxial feature over the bottom isolation layer 240 and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

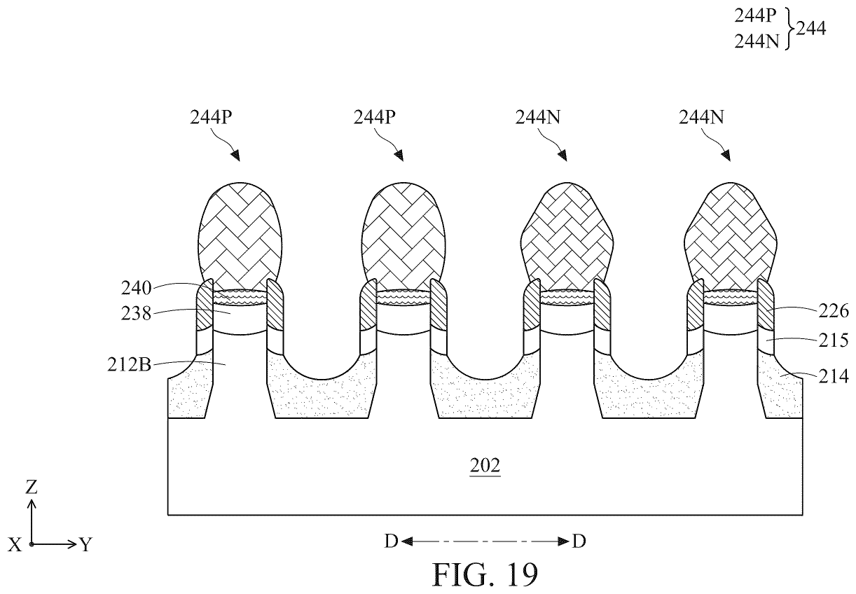

Reference is made to FIG. 19, which includes a fragmentary cross-sectional view across multiple adjacent source/drain regions 212SD. In some embodiments represented in FIG. 19, an n-type source/drain feature 244N may be adjacent to a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface of the bottom isolation layer 240. For ease of illustration and description, the n-type source/drain feature 244N and the p-type source/drain feature 244P may be collectively referred to as the source/drain feature 244, as in FIG. 18. Also as illustrated in FIG. 18, in some embodiments, in the Y-Z plane each source/drain feature 244 may include a portion overhanging the isolation structure 214 and the isolation structure protecting layer 215.

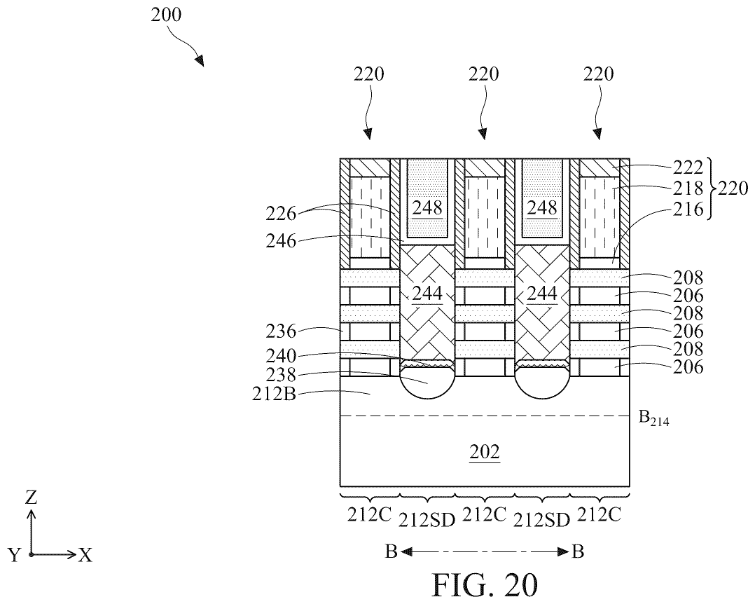

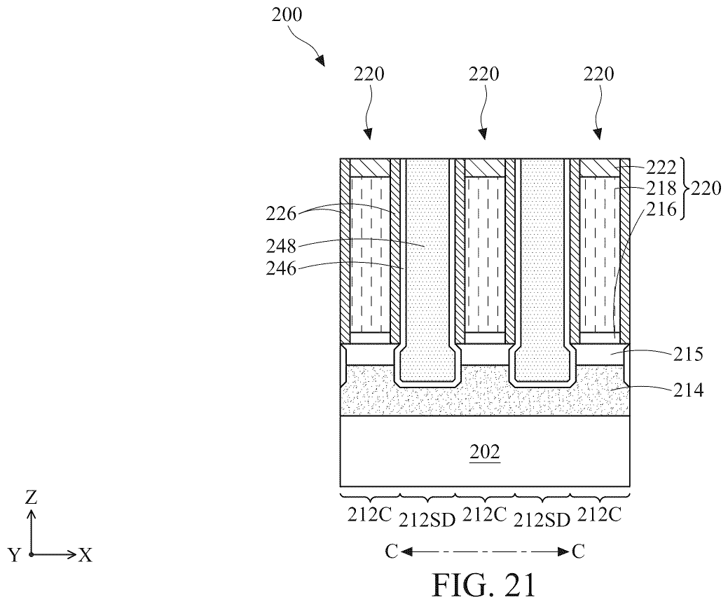

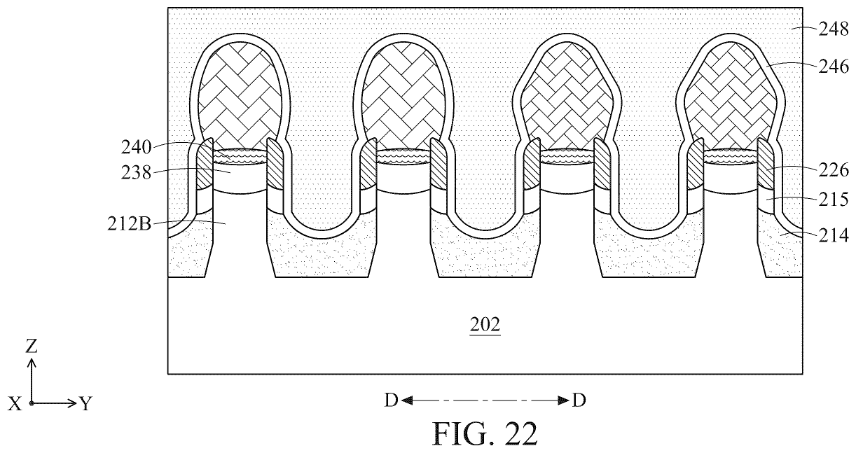

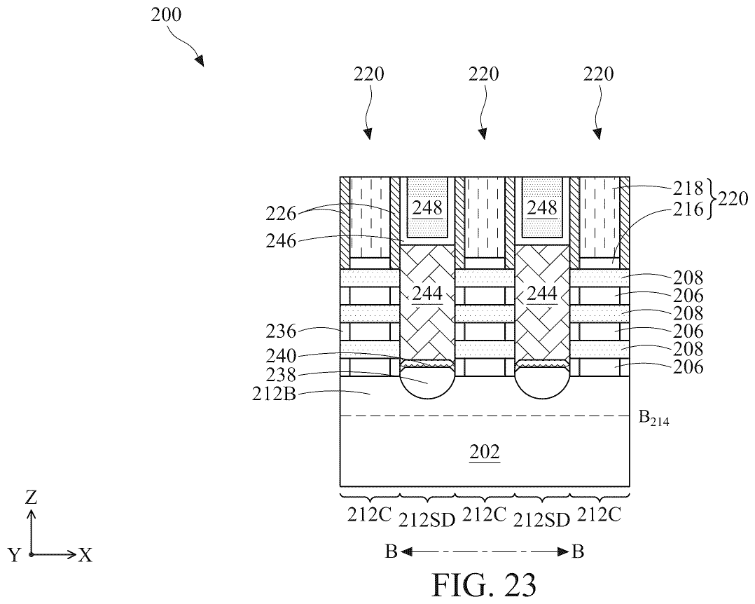

Referring to FIGS. 1 and 20-23, method 100 includes a block 124 where a contact etch stop layer (CESL) 246 and an interlayer dielectric (ILD) layer 248 are deposited in the source/drain regions 212SD. As shown in FIG. 20, the CESL 246 is deposited over the source/drain feature 244. The CESL 246 may include silicon nitride or aluminum nitride. In some implementations, the CESL 246 may be deposited using CVD or ALD. The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. As shown in FIG. 21, the CESL 246 also lines the cavity underneath the isolation structure protecting layer 215. The bottom portions of the CESL 246 and ILD layer 248 extend directly under the gate spacers 226 and are partially embedded in the isolation structure 214. As shown in FIG. 22, the fin spacers 226 are also covered by the CESL 246. As shown in FIG. 23, after the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process. After the planarization, top surfaces of the CESL 246, the ILD layer 248, the gate spacers 226, and the dummy gate stacks 220 are coplanar.

Referring to FIGS. 1 and 24-26, method 100 includes a block 126 where the dummy gate stacks 220 and subsequently the sacrificial layers 206 are selectively removed. The exposure of the dummy gate stack 220 at the conclusion of operations at block 124 allows the removal thereof. The removal of the dummy gate stack 220 may include one or more etching processes that are selective to the materials of the dummy gate stack 220. For example, the removal of the dummy gate stack 220 may be performed using a selective wet etch, a selective dry etch, or a combination thereof that is selective to the dummy gate stack 220. The removal of the dummy gate stacks 220 forms gate trenches 250 that expose the stack of the channel layers 208 and the sacrificial layers 206. After the removal of the dummy gate stack 220, the sacrificial layers 206 in the channel regions 212C are exposed and subsequently removed in a separate etching process. For example, a selective wet etching process or a selective dry etching process may be performed to remove the sacrificial layers 206. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the removal of the sacrificial layers 206, the channel layers 208 are released as channel members (also referred to as channel members 208 hereinafter).

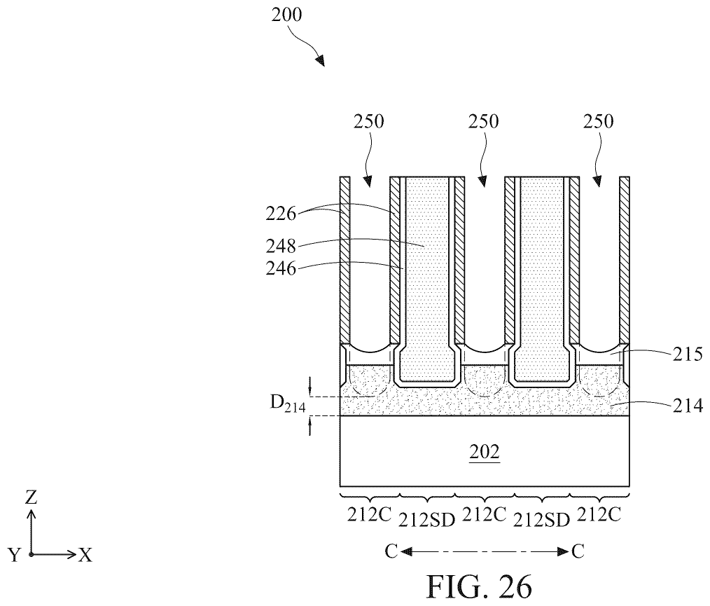

As shown in FIG. 26, the etching processes may partially recess the isolation structure protecting layer 215 to form ditches due to limited etching contrast, causing the bottom surface of the gate trench 250 to extend below the top surface of the isolation structure protecting layer 215. Nevertheless, the isolation structure protecting layer 215 prevents the gate trench 250 from extending through, thereby ensuring that the isolation structure 214 beneath the gate trench 250 remains intact. To illustrate the scenario in which no isolation structure protecting layer 215 is present, a dashed line is added in FIG. 26 to represent the alternative bottom surface of the gate trench 250 that would otherwise extend into the isolation structure 214. In subsequent operations, a metal gate structure will be deposited in the gate trench 250. The vertical distance between the bottom surface of the isolation structure 214 and the bottom surface of the gate trench 250, denoted as D₂₁₄, is the maximum thickness to which the isolation structure 214 can be thinned down in a backside process. Otherwise, the metal gate structure would be exposed from the backside of the semiconductor device 200 and potentially damaged. In other words, the isolation structure 214 must be preserved with a sufficiently large thickness, which in turn limits the height of a backside via for reducing via resistance. On the other hand, when the isolation structure protecting layer 215 is used, the bottom surface of the metal gate structure remains above the top surface of the isolation structure 214. In this case, the isolation structure protecting layer 215 may serve as a thinning stop layer in a backside process, allowing the isolation structure 214 to be substantially removed and enabling the backside via to have a reduced height, thereby reducing its resistance. More details of this approach will be described below.

Referring to FIGS. 1 and 27-29, method 100 includes a block 128 where gate structures 260 (e.g., p-type gate structures 260P for p-type transistors and n-type gate structures 260N for n-type transistors) are formed in the gate trenches 250 to wrap around each of the channel members 208. The gate structure 260 is also referred to as metal gate structure 260 due to its metal-containing layers. In the depicted embodiment, the gate structure 260 includes an interfacial layer 262 interfacing the channel members 208, a high-k dielectric layer 264 over the interfacial layer 262, and a gate electrode layer 266 over the high-k dielectric layer 264. The interfacial layer 262 and the high-k dielectric layer 264 are collectively referred to as a gate dielectric layer.

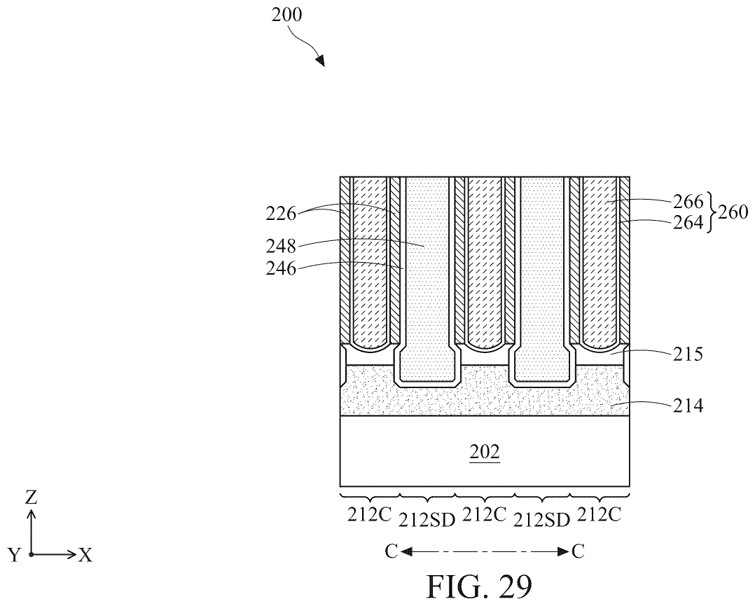

The interfacial layer 262 may include a dielectric material such as silicon oxide, hafnium silicate, or silicon oxynitride. The interfacial layer 262 may be formed by chemical oxidation, thermal oxidation, atomic layer deposition (ALD), chemical vapor deposition (CVD), and/or other suitable method. In the illustrated embodiment, the interfacial layer 262 is formed by thermal oxidating semiconductor materials exposed in the gate trenches 250. Therefore, the interfacial layer 262 is formed on semiconductor surfaces, such as the exposed surfaces of the channel members 208 and the top surface of the fin-shaped base 212B, but not on dielectric surfaces, such as sidewalls of the inner spacers 236, sidewalls of the gate spacers 226, and top surface of the isolation structure protecting layer 215 (FIG. 29). The high-k dielectric layer 264 may include a high-k dielectric material, such as hafnium oxide. Alternatively, the gate dielectric layer may include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the high-k dielectric layer 264 is greater than a dielectric contact of the gate spacers 226. The high-k dielectric layer 264 may be formed by ALD, physical vapor deposition (PVD), CVD, oxidation, and/or other suitable methods. As shown in FIG. 29, the high-k dielectric layer 264 may be conformally deposited on exposed dielectric surfaces exposed in the gate trenches 250.

The gate electrode layer 266 includes a work function metal layer and a metal fill layer over the work function layer. The work function metal layer is a p-type work function metal layer in the p-type transistors or an n-type work function metal layer in the n-type transistors. The p-type work function metal layer comprises a metal selected from, but not limited to, the group of titanium nitride, tantalum nitride, ruthenium, molybdenum, tungsten, platinum, or combinations thereof. The n-type work function metal layer comprises a metal selected from, but not limited to, the group of titanium, aluminum, tantalum carbide, tantalum carbide nitride, tantalum silicon nitride, or combinations thereof. In some embodiments, the p-type or n-type work function metal layer includes a plurality of layers deposited by CVD, PVD, and/or other suitable process. The metal fill layer includes aluminum, tungsten, cobalt, copper, and/or other suitable materials, and is formed by CVD, PVD, plating, and/or other suitable processes.

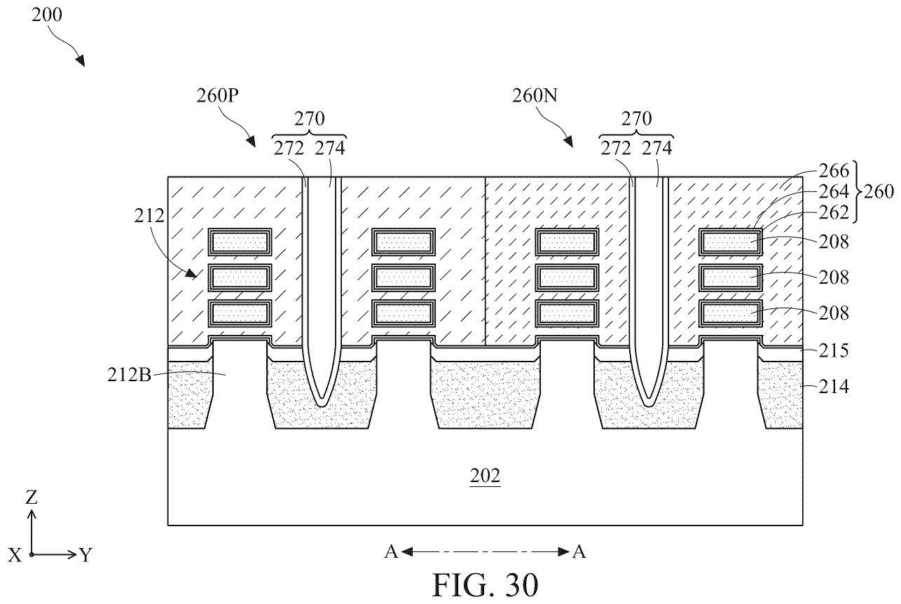

Referring to FIGS. 1 and 30, method 100 includes a block 130 where gate-end dielectric features 270 are formed. The gate-end dielectric feature 270 cuts an otherwise continuous gate structures 260 into segments, which may also be referred to as cut-metal-gate (CMG) feature 270. In the illustrated embodiment, the gate-end dielectric features 270 isolate the n-type and p-type GAA transistors as dual transistors in a CMOS device from other adjacent devices. The gate-end dielectric feature 270 may be a single layer structure or a multi-layer structure. For a multi-layer structure, the gate-end dielectric feature 270 may include a dielectric liner 272 and a dielectric fill layer 274. In an exemplary process flow, forming the gate-end dielectric feature 270 includes etching through the gate structure 260 to form a CMG trench, which may also extend through the isolation structure protecting layer 215 and into the isolation structure 214 for better isolation, conformally depositing the dielectric liner 272 on sidewalls and bottom surface of the CMG trench, depositing the dielectric fill layer 274 filling the CMG trench, and performing a planarization process (e.g., CMP) to remove excess portions of the dielectric materials. In some embodiments, the dielectric liner 272 is an oxide (e.g., silicon oxide), and the dielectric fill layer 274 is free of oxygen, such as a nitride (e.g., silicon nitride or silicon carbonitride). The dielectric fill layer 274 may be deposited by ALD, CVD, PVD, or other suitable processes. The dielectric liner 272 and the dielectric fill layer 274 collectively define the gate-end dielectric feature 270.

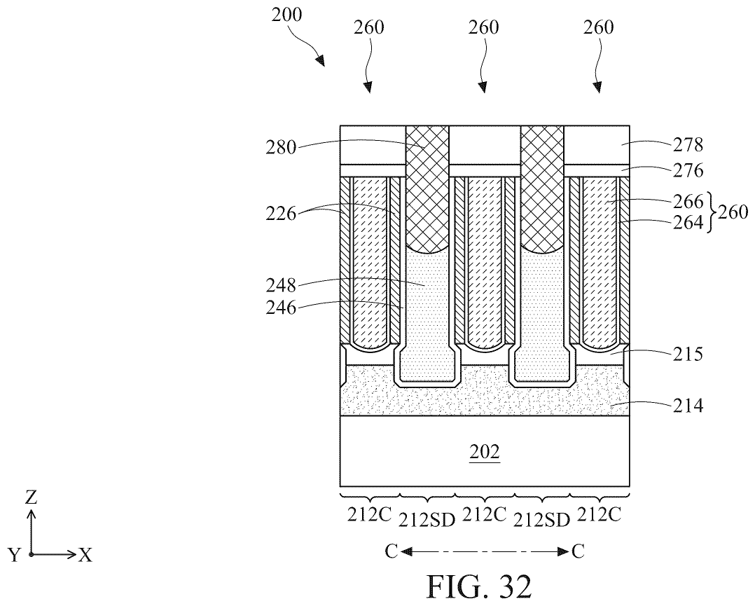

Referring to FIGS. 1 and 31-32, method 100 includes a block 132 where source/drain contact plugs 280 and optional silicide features 282 between the source/drain contact plugs 280 and the source/drain feature 244 are formed in the source/drain regions 212SD. In an exemplary process, a capping layer 276 (also referred to as etch stop layer 276) and a second ILD layer 278 are deposited on the semiconductor device 200. In some embodiments, a thickness of the ILD layer 248 is greater than a thickness of the second ILD layer 278. Subsequently, contact holes are formed by etching through the second ILD layer 278, the capping layer 276, the ILD layer 248, and the CESL 246. The etching process may be a self-aligned process such that the portion of the ILD layer 248 above the source/drain feature 244 is removed using the vertical sidewalls of the CESL 246 as an etch stop layer. An upper portion of the source/drain feature 244 may optionally be etched to have a concave shape as a bottom of the contact hole. The silicide features 282 are formed at the bottom of the contact holes. The silicide features 282 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, source/drain contact plugs 280 are formed on the silicide features 282. Each source/drain contact plug 280 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. An electrical conductivity of the silicide feature 282 is between an electrical conductivity of the source/drain feature 244 and an electrical conductivity of the source/drain contact plug 280, and the electrical conductivity of the source/drain contact plug 280 is greater than the electrical conductivity of the source/drain feature 244. The silicide feature 282 and the source/drain contact plug 280 may be collectively referred to as the source/drain contact. As shown in FIG. 32, in the cross-section C-C the source/drain contact plugs 280 extends further down than in the cross-section B-B and directly lands on the bottom portion of the ILD layer 248 with no silicide features 282 therebetween.

Referring to FIGS. 1 and 33-34, the method 100 includes a block 134 where the frontside of the semiconductor device 200 is attached to a carrier 284 and flipped up upside down. This makes the semiconductor device 200 accessible from the backside of the semiconductor device 200 for further processing. Operations at the block 134 may use any suitable attaching processes, such as direct bonding, hybrid bonding, using adhesive, or other bonding methods. Operations at block 134 may further include alignment, annealing, and/or other processes. The carrier 284 may be a silicon wafer in some embodiments.

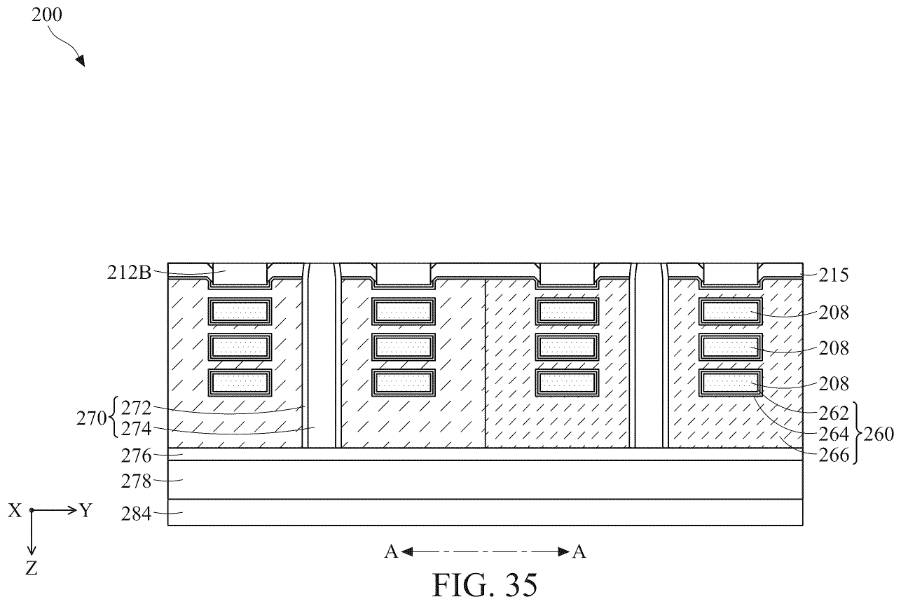

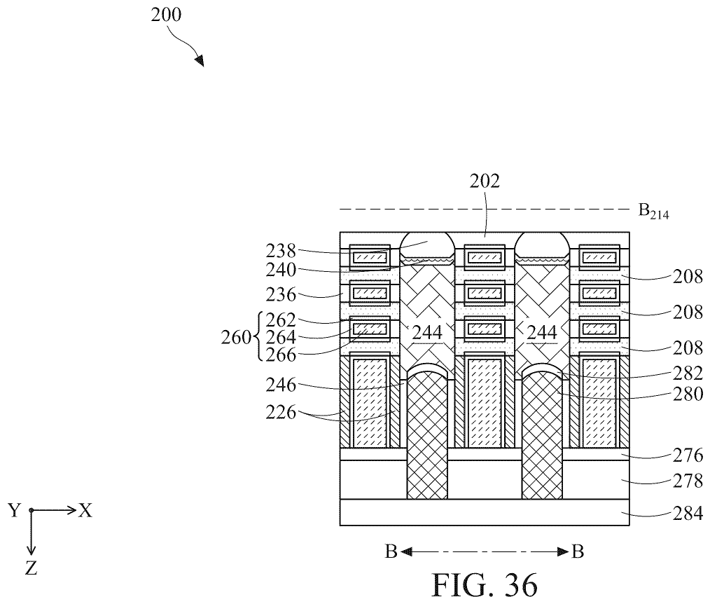

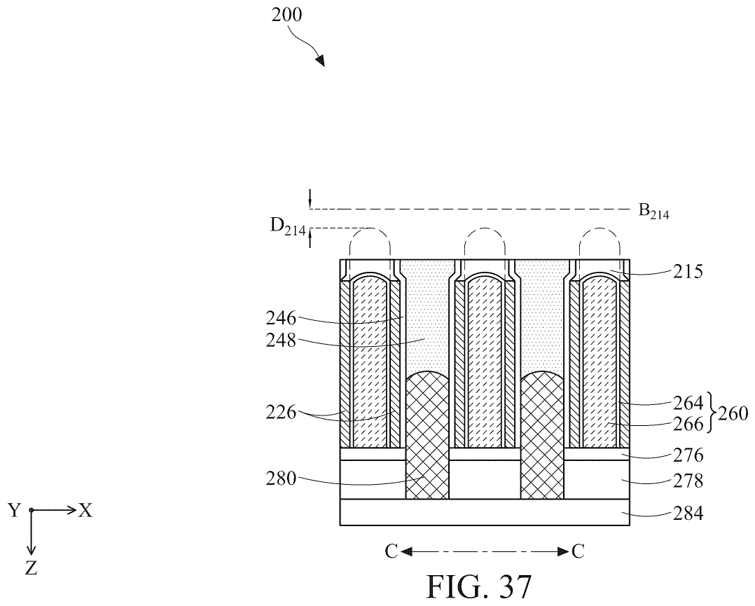

Referring to FIGS. 1 and 35-37, the method 100 includes a block 136 where the semiconductor device 200 is thinned down from the backside. In some embodiments, the thinning process may involve mechanical grinding and/or chemical thinning. Initially, a substantial amount of substrate material is removed from the substrate 202 through mechanical grinding. Subsequently, a chemical thinning process is employed, during which an etching chemical is applied to the backside of the substrate 202 for further thinning, including the removal of the isolation structure 214. The thinning process utilizes the isolation structure protecting layer 215 as a thinning stop layer, ensuring the process halts at the bottom surface of the isolation structure protecting layer 215. Since the material compositions of the isolation structure 214 and the isolation structure protecting layer 215 differ, the exposure of the isolation structure protecting layer 215 results in a significant change in the end-point signal, thereby providing high-precision thickness control. In the illustrated embodiment, once the isolation structure protecting layer 215 is exposed, additional features, such as the fin-shaped base 212B (FIG. 35), the separation layer 238 (FIG. 36), and the CESL 246 and ILD layer 248 (FIG. 37), are also exposed on the backside of the semiconductor device 200.

As illustrated in FIG. 37, the isolation structure protecting layer 215, acting as a thinning stop layer, remains and protects the bottom surfaces of the gate structures 260 from exposure during the backside thinning process. To depict the scenario without the isolation structure protecting layer 215, a dashed line is included in FIG. 37 to represent the alternative bottom surface of the gate structures 260, which would extend into the isolation structure 214. The vertical distance (D₂₁₄) between the bottom surface B₂₁₄ of the isolation structure 214 and the bottom surface of the gate structures 260 represents the maximum allowable thickness to which the isolation structure 214 can be thinned without exposing the gate structures 260. Exposing the gate structures 260 from the backside would risk potential damage. Consequently, the isolation structure 214 must be preserved with sufficient thickness, limiting the height of the backside via and thereby constraining via resistance reduction. In contrast, when the isolation structure protecting layer 215 is used, the isolation structure 214 can be substantially removed, allowing for the formation of a backside via with a reduced height. This reduced via height results in decreased resistance in the backside interconnect routing.

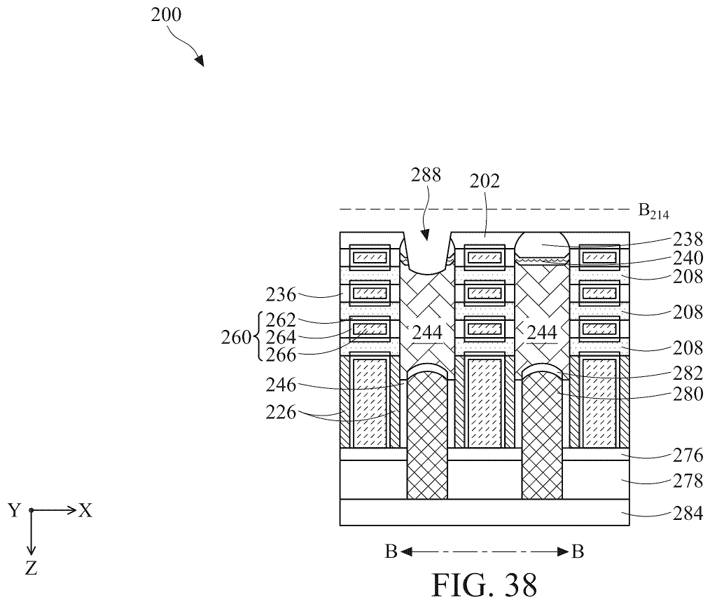

Referring to FIGS. 1 and 38, the method 100 includes a block 138 where a backside via opening 288 is formed to expose the backside of the source/drain feature 244. In one embodiment, the exposed source/drain feature 244 is a source feature, while drain feature remains covered. Operations at the block 138 may include selectively etching the separation layer 238 to form an initial opening exposing the bottom isolation layer 240, and subsequently selectively etching the bottom isolation layer 240 to extend the opening to the bottom surface of the source/drain feature 244. In the X-Z plane, the backside via opening 288 extends through the separation layer 238 and the bottom isolation layer 240. Some residual portions of the separation layer 238 and the bottom isolation layer 240 may remain at corner regions. In the illustrated embodiment, the bottom of the backside via opening 288 has a concave profile that is below the bottommost one of the inner spacers 236.

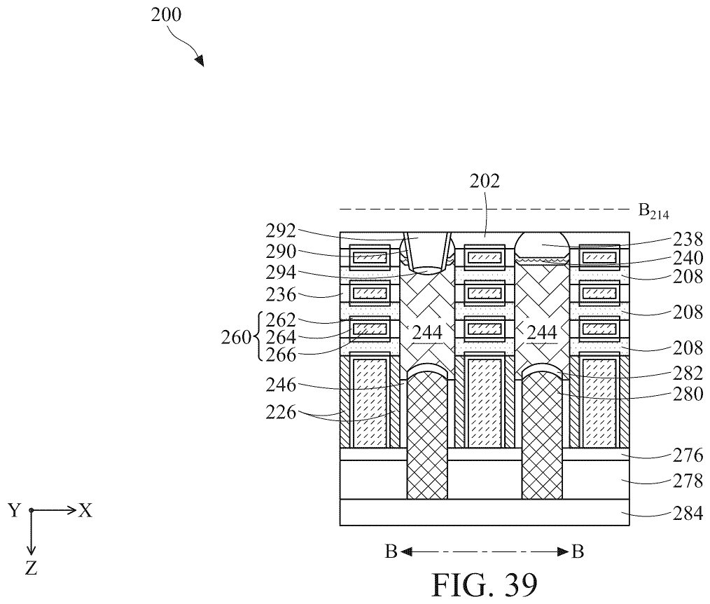

Referring to FIGS. 1 and 39, the method 100 includes a block 140 where a spacer layer 290 and a backside via 292 are formed in the backside via opening 288. The spacer layer 290 may include a dielectric material such as silicon oxide, silicon nitride, silicon carbide, silicon oxynitride, SiCN films, silicon oxycarbide, SiOCN films, and/or combinations thereof. By way of example, the spacer layer 290 may be formed by blanket depositing a dielectric material layer in a conformal manner over the backside of the semiconductor device 200 using processes such as CVD, SACVD, ALD, PVD, or other suitable process. In the illustrated embodiment, the deposition of the dielectric material layer is followed by an etching-back (e.g., anisotropically) process to remove the dielectric material layer from horizontal surfaces and expose the bottom surface of the source/drain feature 244. The dielectric material layer may remain on the sidewalls of the backside via opening 288 as the spacer layer 290. The conductive material of the backside via 292 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. The conductive material may cover the backside surface of the semiconductor device 200. The spacer layer 290 functions as a diffusion barrier layer to prevent the metallic elements in the backside via 292 diffusing into surrounding dielectric features. In one embodiment, the backside via 292 directly contacts the source/drain features 244. Alternatively, in an embodiment, a silicide feature 294 is optionally formed between the source/drain feature 244 and the backside via 292 to further reduce contact resistance. The silicide feature 294 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. The silicide feature 294 and the backside via 292 may be collectively referred to as the backside contact. A planarization operation, such as a CMP process, is performed to remove excessive conductive material of the backside via 292. The isolation structure protecting layer 215 may function as a stop layer for the planarization operation, such that the backside via 292, the spacer layer 290, the neighboring separation layer 238, the CESL 246, and the ILD layer 248 may have coplanar bottom surfaces.

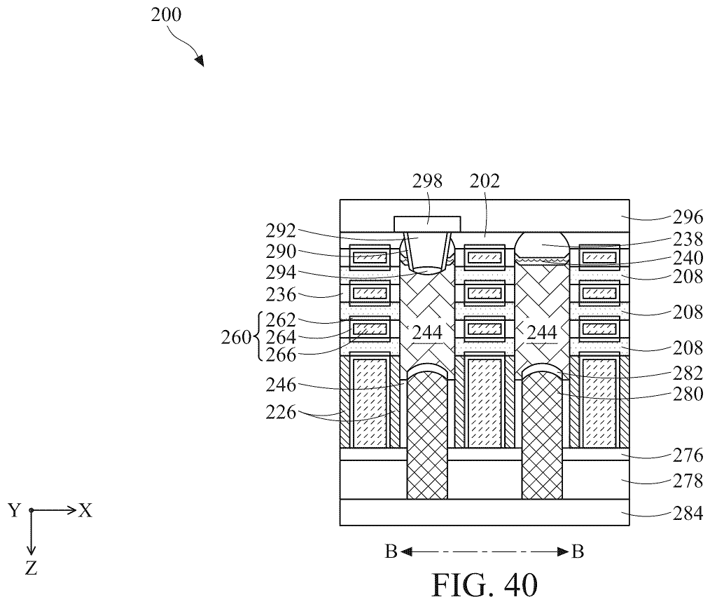

Referring to FIGS. 1 and 40, the method 100 includes a block 142 where one or more backside interconnect layers 296 are formed. The backside interconnect layer 296 includes backside metal lines, such as the depicted backside metal line 298, embedded therein. The backside metal line 298 electrically connects to the source/drain feature 244 through the backside via 292. The reduced height of the backside via 292 reduces contact resistance between the backside metal line 298 and the source/drain feature 244. In an embodiment, the backside metal line 298 may be formed using a damascene process, a dual-damascene process, a metal patterning process, or other suitable processes. The backside metal line 298 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be deposited by CVD, PVD, ALD, plating, or other suitable processes. In some embodiments, the backside metal line 298 is part of the backside power rails. In one example, the source/drain feature 244 in electrical connection with the backside metal line 298 is a source feature, such as a source feature of a pull-down transistor in a static random-access memory (SRAM) cell, and the backside metal line 298 is an electric grounding line. In another example, the source/drain feature 244 in electrical connection with the backside metal line 298 is a source feature, such as a source feature of a pull-up transistor in an SRAM cell and the backside metal line 298 is a power supply line. In some other embodiments, the backside metal line 298 is a signal line and the source/drain feature 244 in electrical connection with the backside metal line 298 is a drain feature, such as a drain feature of a pull-up or pull-down transistor in an SRAM cell. Although not shown in FIG. 40, the backside interconnect layers 297 may include other contacts, vias, wires, and/or other conductive features. Having backside interconnect structures beneficially increases the number of metal tracks available in the semiconductor device 200 for directly connecting to source/drain features. The backside power rails and/or signal lines may have wider dimension than the first level metal (M0) tracks on the frontside of the semiconductor device 200, which beneficially reduces the backside power rail resistance.

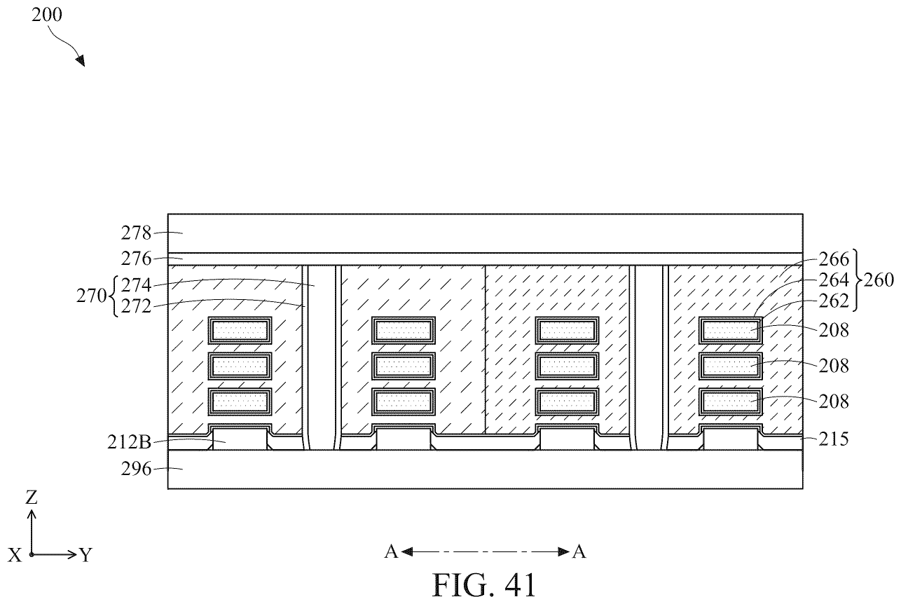

After operations at the block 142, the semiconductor device 200 is flipped back, as illustrated in FIGS. 41-43 for respective cross-sections A-A, B-B, and C-C, to receive further fabrication processes to finish the final device. For example, the method 100 may remove the carrier substrate, form more interconnect layers on the frontside, form a passivation layer atop the semiconductor device 200, dice the wafer into chips, and package the chips.

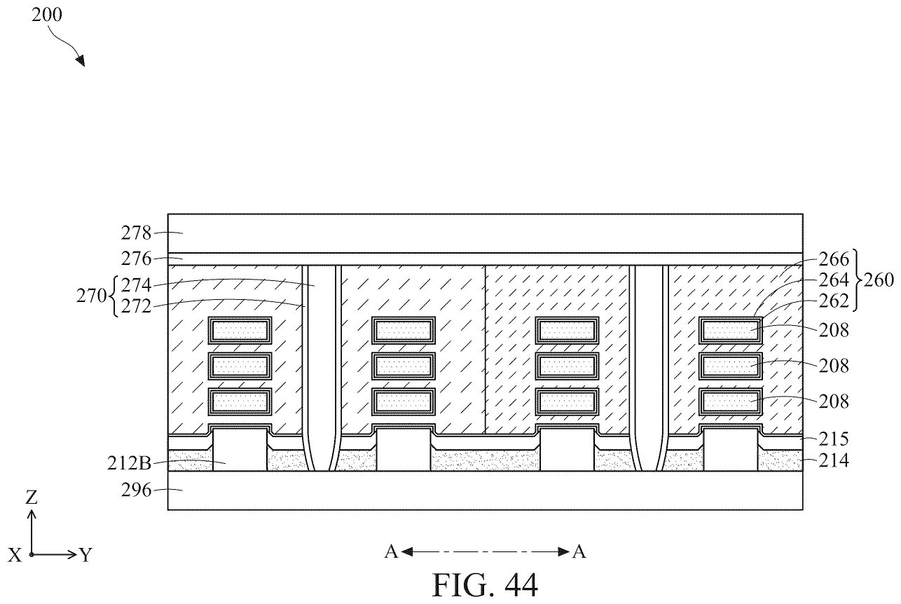

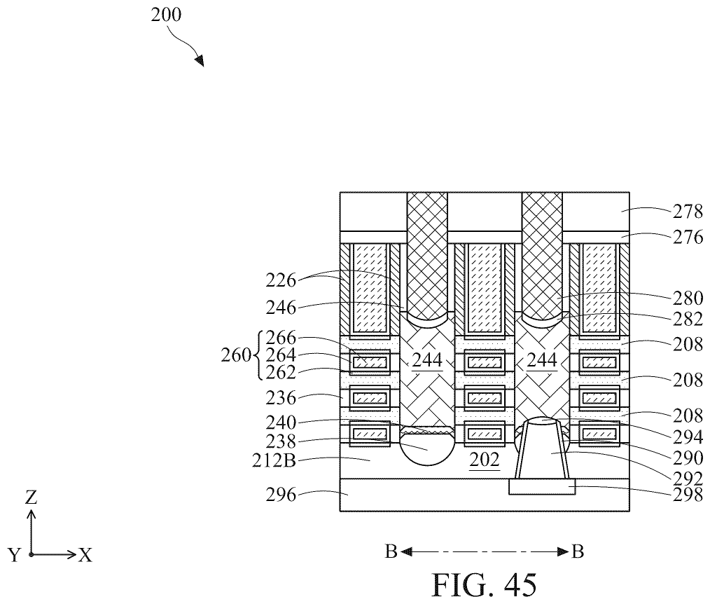

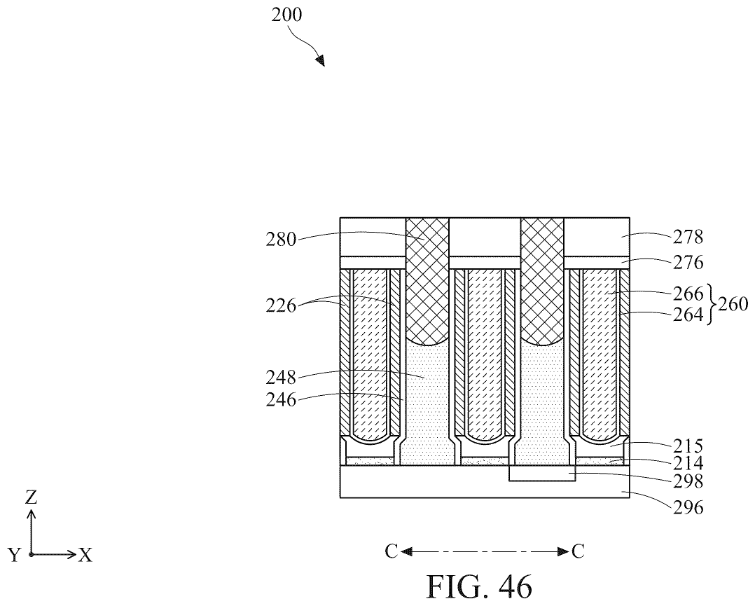

FIGS. 44-46 illustrate an alternative embodiment of the semiconductor device 200 at its cross-sections A-A, B-B, and C-C. The difference between the alternative embodiment in FIG. 44-46 and the embodiment in FIGS. 41-43 is that the backside thinning process at block 136 may thin down the isolation structure 214 without substantially removing it. The backside thinning process may use a timer mode to control the remaining thickness of the isolation structure 214. Nonetheless, the existence of the isolation structure protecting layer 215 allows the isolation structure 214 to be more aggressively thinned down without the concern of accidentally exposing the gate structures 260 from the backside of the semiconductor device 200. As shown in FIG. 44, the isolation structure 214 interposes the isolation structure protecting layer 215 and the backside interconnect layer 296. In some embodiments, the thickness of the remaining isolation structure 214 is larger than the thickness of the isolation structure protecting layer 215; in some other embodiments, the thickness of the remaining isolation structure 214 is smaller than the thickness of the isolation structure protecting layer 215, depending on application needs. As shown in FIG. 45, the bottom surface of the neighboring separation layer 238 may remain covered by the substrate 202 due to the extra thickness of the substrate 202 corresponding to the thickness of the remaining isolation structure 214. As shown in FIG. 46, the isolation structure 214 interposes the isolation structure protecting layer 215 and the backside interconnect layer 296.

Although not intended to be limiting, embodiments of the present disclosure provide one or more of the following advantages. For example, embodiments of the present disclosure enable the formation of backside vias with reduced height by incorporating an isolation structure protecting layer. By depositing the isolation structure protecting layer on the frontside of the isolation structure before forming metal gate structures, the isolation structure can be protected from etching loss during frontside manufacturing. Additionally, the isolation structure protecting layer serves as a thinning stop layer, ensuring that metal gate structures are not exposed during backside thinning. Consequently, the isolation structure can be substantially removed during the backside process, resulting in significantly lower backside via height and reduced associated resistance, thereby enhancing overall device performance.

In one exemplary aspect, the present disclosure is directed to a method. The method includes forming a stack on a substrate, the stack having a plurality of channel layers interleaved by a plurality of sacrificial layers, patterning the stack and the substrate to form a first region and a second region each extending lengthwise in a first direction, the first region comprising a first active region and a first base region, the second region comprising a second active region and a second base region, forming an isolation structure between the first base region and the second base region, the isolation structure interfacing a sidewall of the first base region and a sidewall of the second base region, depositing an isolation structure protecting layer on the isolation structure, forming a dummy gate stack across the first active region and the second active region, the dummy gate stack interfacing a top surface of the isolation structure protecting layer, depositing gate spacers on sidewalls of the dummy gate stack, recessing the first and second active regions outside of the dummy gate stack and the gate spacers to form first and second trenches, respectively, forming a first source/drain feature in the first trench and a second source/drain feature in the second trench, a portion of the first source/drain feature overhanging the isolation structure along a second direction different from the first direction, a portion of the second source/drain feature overhanging the isolation structure along the second direction, removing the dummy gate stack to form a gate trench, the gate trench exposing the isolation structure protecting layer, removing the sacrificial layers from the gate trench, depositing a gate structure in the gate trench, the gate structure interfacing the top surface of the isolation structure protecting layer, thinning the substrate and the isolation structure, forming a backside opening exposing a bottom surface of the first source/drain feature, and forming a backside via in the backside opening and in electrical coupling with the first source/drain feature. In some embodiments, the thinning exposes a bottom surface of the isolation structure protecting layer. In some embodiments, the thinning fully removes the isolation structure. In some embodiments, the isolation structure includes an oxide, and the isolation structure protecting layer includes a nitride. In some embodiments, prior to the forming of the first and second source/drain features, a portion of the isolation structure protecting layer between the first and second base regions is etched through. In some embodiments, the method further includes depositing an interlayer dielectric layer over the first and second source/drain features. A bottom portion of the interlayer dielectric layer extends below a bottom surface of the isolation structure protecting layer. In some embodiments, the removing of the dummy gate stack forms a ditch on the isolation structure protecting layer, such that a bottom portion of the gate structure in the ditch is below a top surface of the isolation structure protecting layer. In some embodiments, the method further includes prior to the forming of the first and second source/drain features, forming a first buffer epitaxial layer in the first trench and a second buffer epitaxial layer in the second trench. The thinning exposes the first buffer epitaxial layer. In some embodiments, between the first and second base regions, a top surface of the isolation structure protecting layer has a dishing profile. In some embodiments, an edge of the dishing profile interfaces a sidewall of a bottommost one of the sacrificial layers.

In another exemplary aspect, the present disclosure is directed to a method. The method includes providing a structure having a frontside and a backside, the structure including a substrate at the backside of the structure and a fin-shaped structure at the frontside of the structure, forming an isolation structure on sidewalls of the fin-shaped structure, forming an isolation structure protecting layer on the isolation structure, epitaxially growing a source/drain feature on the fin-shaped structure, depositing a contact etch stop layer over the source/drain feature, depositing a first interlayer dielectric layer over the contact etch stop layer, depositing a capping layer over a top surface of the contact etch stop layer and a top surface of the first interlayer dielectric layer, depositing a second interlayer dielectric layer over the capping layer, a thickness of the first interlayer dielectric layer greater than a thickness of the second interlayer dielectric layer, forming a source/drain contact plug disposed in the first interlayer dielectric layer to electrically couple to the source/drain feature, forming a metal silicide layer disposed between the source/drain feature and the source/drain contact plug, an electrical conductivity of the metal silicide layer between an electrical conductivity of the source/drain feature and an electrical conductivity of the source/drain contact plug, the metal silicide layer comprising a curved profile, thinning down the structure from the backside of the structure until the isolation structure protecting layer is exposed, forming an opening exposing a bottom surface of the source/drain feature, and depositing a backside via in the opening. In some embodiments, the thinning down of the structure also exposes the first interlayer dielectric layer from the backside of the structure. In some embodiments, the method further includes forming an undoped epitaxial layer under the source/drain feature. The thinning down of the structure also exposes the undoped epitaxial layer. In some embodiments, the method further includes forming a dummy gate stack across the fin-shaped structure, replacing the dummy gate stack with a metal gate structure, the metal gate structure interfacing a top surface of the isolation structure protecting layer, and forming a dielectric feature dividing the metal gate structure. The thinning down of the structure also exposes the dielectric feature. In some embodiments, a thickness of the isolation structure protecting layer ranges from about 10 nm to about 50 nm. In some embodiments, the method further includes prior to the epitaxially growing of the source/drain feature, etching through the isolation structure protecting layer.

In yet another exemplary aspect, the present disclosure is directed to a semiconductor structure. The semiconductor structure includes first and second source/drain features, one or more nanostructures connecting the first and second source/drain features, a gate structure engaging the one or more nanostructures, the gate structure comprising a gate dielectric layer and a gate electrode layer over the gate dielectric layer, a gate spacer extending along a sidewall of the gate structure, a dielectric constant of the gate dielectric layer greater than a dielectric constant of the gate spacer, an interlayer dielectric layer disposed over the first and second source/drain features, a source/drain contact extending through the interlayer dielectric layer to electrically couple to the first source/drain feature, an electrical conductivity of the source/drain contact is greater than an electrical conductivity of the first source/drain feature, a protecting layer disposed under and interfacing a bottom surface of the gate structure, a bottom surface of the interlayer dielectric layer and a bottom surface of the protecting layer being coplanar, a backside dielectric layer disposed on the bottom surface of the protecting layer, a metal line embedded in the backside dielectric layer, and a backside via directly under the first source/drain feature and electrically connecting the metal line to the first source/drain feature. In some embodiments, the bottom surface of the gate structure is below a top surface of the protecting layer. In some embodiments, the protecting layer prevents the gate structure from interfacing the backside dielectric layer. In some embodiments, a top surface of the metal line interfaces the bottom surface of the interlayer dielectric layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack on a substrate, the stack having a plurality of channel layers interleaved by a plurality of sacrificial layers;
patterning the stack and the substrate to form a first region and a second region each extending lengthwise in a first direction, the first region comprising a first active region and a first base region, the second region comprising a second active region and a second base region;
forming an isolation structure between the first base region and the second base region, wherein the isolation structure interfaces a sidewall of the first base region and a sidewall of the second base region;
depositing an isolation structure protecting layer on the isolation structure;
forming a dummy gate stack across the first active region and the second active region, the dummy gate stack interfacing a top surface of the isolation structure protecting layer;
depositing gate spacers on sidewalls of the dummy gate stack;
recessing the first and second active regions outside of the dummy gate stack and the gate spacers to form first and second trenches, respectively;
forming a first source/drain feature in the first trench and a second source/drain feature in the second trench, a portion of the first source/drain feature overhanging the isolation structure along a second direction different from the first direction, a portion of the second source/drain feature overhanging the isolation structure along the second direction;
removing the dummy gate stack to form a gate trench, the gate trench exposing the isolation structure protecting layer;
removing the sacrificial layers from the gate trench;
depositing a gate structure in the gate trench, the gate structure interfacing the top surface of the isolation structure protecting layer;
thinning the substrate and the isolation structure;
forming a backside opening exposing a bottom surface of the first source/drain feature; and
forming a backside via in the backside opening and in electrical coupling with the first source/drain feature.

2. The method of claim 1, wherein the thinning exposes a bottom surface of the isolation structure protecting layer.

3. The method of claim 1, wherein the thinning fully removes the isolation structure.

4. The method of claim 1, wherein the isolation structure includes an oxide, and the isolation structure protecting layer includes a nitride.

5. The method of claim 1, wherein prior to the forming of the first and second source/drain features, a portion of the isolation structure protecting layer between the first and second base regions is etched through.

6. The method of claim 5, further comprising:
depositing an interlayer dielectric layer over the first and second source/drain features, wherein a bottom portion of the interlayer dielectric layer extends below a bottom surface of the isolation structure protecting layer.

7. The method of claim 1, wherein the removing of the dummy gate stack forms a ditch on the isolation structure protecting layer, such that a bottom portion of the gate structure in the ditch is below a top surface of the isolation structure protecting layer.

8. The method of claim 1, further comprising:
prior to the forming of the first and second source/drain features, forming a first buffer epitaxial layer in the first trench and a second buffer epitaxial layer in the second trench,
wherein the thinning exposes the first buffer epitaxial layer.

9. The method of claim 1, wherein, between the first and second base regions, a top surface of the isolation structure protecting layer has a dishing profile.

10. The method of claim 9, wherein an edge of the dishing profile interfaces a sidewall of a bottommost one of the sacrificial layers.

11. A method, comprising:
providing a structure having a frontside and a backside, the structure including a substrate at the backside of the structure and a fin-shaped structure at the frontside of the structure;
forming an isolation structure on sidewalls of the fin-shaped structure;
forming an isolation structure protecting layer on the isolation structure;
epitaxially growing a source/drain feature on the fin-shaped structure;
depositing a contact etch stop layer over the source/drain feature;
depositing a first interlayer dielectric layer over the contact etch stop layer;
depositing a capping layer over a top surface of the contact etch stop layer and a top surface of the first interlayer dielectric layer;
depositing a second interlayer dielectric layer over the capping layer, wherein a thickness of the first interlayer dielectric layer is greater than a thickness of the second interlayer dielectric layer;
forming a source/drain contact plug disposed in the first interlayer dielectric layer to electrically couple to the source/drain feature;
forming a metal silicide layer disposed between the source/drain feature and the source/drain contact plug, wherein an electrical conductivity of the metal silicide layer is between an electrical conductivity of the source/drain feature and an electrical conductivity of the source/drain contact plug, wherein the metal silicide layer comprises a curved profile;
thinning down the structure from the backside of the structure until the isolation structure protecting layer is exposed;
forming an opening exposing a bottom surface of the source/drain feature; and
depositing a backside via in the opening.

12. The method of claim 11, wherein the thinning down of the structure also exposes the first interlayer dielectric layer from the backside of the structure.

13. The method of claim 11, further comprising:
forming an undoped epitaxial layer under the source/drain feature, wherein the thinning down of the structure also exposes the undoped epitaxial layer.

14. The method of claim 11, further comprising:
forming a dummy gate stack across the fin-shaped structure;
replacing the dummy gate stack with a metal gate structure, the metal gate structure interfacing a top surface of the isolation structure protecting layer; and
forming a dielectric feature dividing the metal gate structure,
wherein the thinning down of the structure also exposes the dielectric feature.

15. The method of claim 11, wherein a thickness of the isolation structure protecting layer ranges from about 10 nm to about 50 nm.

16. The method of claim 11, further comprising:
prior to the epitaxially growing of the source/drain feature, etching through the isolation structure protecting layer.

17. A semiconductor structure, comprising:
first and second source/drain features;
one or more nanostructures connecting the first and second source/drain features;
a gate structure engaging the one or more nanostructures, the gate structure comprising a gate dielectric layer and a gate electrode layer over the gate dielectric layer;
a gate spacer extending along a sidewall of the gate structure, wherein a dielectric constant of the gate dielectric layer is greater than a dielectric constant of the gate spacer;
an interlayer dielectric layer disposed over the first and second source/drain features;
a source/drain contact extending through the interlayer dielectric layer to electrically couple to the first source/drain feature, wherein an electrical conductivity of the source/drain contact is greater than an electrical conductivity of the first source/drain feature;
a protecting layer disposed under and interfacing a bottom surface of the gate structure, wherein a bottom surface of the interlayer dielectric layer and a bottom surface of the protecting layer are coplanar;
a backside dielectric layer disposed on the bottom surface of the protecting layer;
a metal line embedded in the backside dielectric layer; and
a backside via directly under the first source/drain feature and electrically connecting the metal line to the first source/drain feature.

18. The semiconductor structure of claim 17, wherein the bottom surface of the gate structure is below a top surface of the protecting layer.

19. The semiconductor structure of claim 17, wherein the protecting layer prevents the gate structure from interfacing the backside dielectric layer.

20. The semiconductor structure of claim 17, wherein a top surface of the metal line interfaces the bottom surface of the interlayer dielectric layer.
